(19) United States
(12) Patent Application Publication
(10) Pub. No.: US 2022/0343935 A1
(43) Pub. Date: Oct. 27, 2022

(54) ROOM SOUNDS MODES

(71) Applicant: Sonos, Inc., Santa Barbara, CA (US)

(72) Inventors: Jonathan Cole Harris, Santa Barbara, CA (US); Dayn Wilberding, Portland, OR (US); Paul Andrew Bates, Santa Barbara, CA (US)

(21) Appl. No.: 17/660,693

(22) Filed: Apr. 26, 2022

Related U.S. Application Data
(60) Provisional application No. 63/180,495, filed on Apr. 27, 2021.

(51) Int. Cl. G10L 21/0364; H04R 3/04; G06F 3/16; G10L 21/0232

(52) U.S. Cl. CPC G10L 21/0364; H04R 3/04; G06F 3/165; G06F 3/167; G10L 21/0232

(57) ABSTRACT

Example techniques described herein involve a media playback system of one or more playback devices that are operable in a plurality of modes. Operating in a given mode may enhance a use case corresponding to the mode. For instance, the plurality of modes may include a foreground mode, which may enhance active listening to the playback device. The plurality of modes may also include a background mode, which may enhance passive listening to the playback device by facilitating other activities during passive listening. In some example implementations, the plurality of modes are non-contemporary; when operating in one mode, the playback device will not be operating in the other modes, and vice versa.

### CROSS-REFERENCE TO RELATED APPLICATION

This application claims the benefit of priority to U.S. provisional Patent Application No. 63/180,495, filed Apr. 27, 2021, which incorporated herein by reference in its entirety.

### FIELD OF THE DISCLOSURE

The present technology relates to consumer goods and, more particularly, to methods, systems, products, features, services, and other elements directed to voice-assisted control of media playback systems or some aspect thereof.

### BACKGROUND

Options for accessing and listening to digital audio in an out-loud setting were limited until in 2002, when SONOS, Inc. began development of a new type of playback system. Sonos then filed one of its first patent applications in 2003, entitled “Method for Synchronizing Audio Playback between Multiple Networked Devices,” and began offering its first media playback systems for sale in 2005. The Sonos Wireless Home Sound System enables people to experience music from many sources via one or more networked playback devices. Through a software control application installed on a controller (e.g., smartphone, tablet, computer, voice input device), one can play what she wants in any room having a networked playback device. Media content (e.g., songs, podcasts, video sound) can be streamed to playback devices such that each room with a playback device can play back corresponding different media content. In addition, rooms can be grouped together for synchronous playback of the same media content, and/or the same media content can be heard in all rooms synchronously.

### BRIEF DESCRIPTION OF THE DRAWINGS

Features, aspects, and advantages of the presently disclosed technology may be better understood with regard to the following description, appended claims, and accompanying drawings where:

Features, aspects, and advantages of the presently disclosed technology may be better understood with regard to the following description, appended claims, and accompanying drawings, as listed below. A person skilled in the relevant art will understand that the features shown in the drawings are for purposes of illustrations, and variations, including different and/or additional features and arrangements thereof, are possible.

FIG. 1A is a partial cutaway view of an environment having a media playback system configured in accordance with aspects of the disclosed technology.

FIG. 1B is a schematic diagram of the media playback system of FIG. 1A and one or more networks.

FIG. 2A is a functional block diagram of an example playback device.

FIG. 2B is an isometric diagram of an example housing of the playback device of FIG. 2A.

FIG. 2C is a diagram of an example voice input.

FIG. 2D is a graph depicting an example sound specimen in accordance with aspects of the disclosure.

FIGS. 3A, 3B, 3C, 3D and 3E are diagrams showing example playback device configurations in accordance with aspects of the disclosure.

FIG. 4 is a functional block diagram of an example controller device in accordance with aspects of the disclosure.

FIGS. 5A and 5B are controller interfaces in accordance with aspects of the disclosure.

FIG. 6 is a message flow diagram of a media playback system.

FIGS. 7A, 7B, 7C, 7D, 7E, and 7F are diagrams illustrating example room sound modes in accordance with aspects of the disclosed technology.

FIGS. 8A and 8B are functional block diagrams illustrating example state diagrams in accordance with aspects of the disclosed technology.

FIGS. 9A, 9B, 9C, and 9D are functional block diagrams illustrating example triggering in accordance with aspects of the disclosed technology.

FIGS. 10A and 10B are controller interfaces in accordance with aspects of the disclosed technology.

FIG. 11 is a flow diagram of an example method to process command intermediates in accordance with aspects of the disclosed technology.

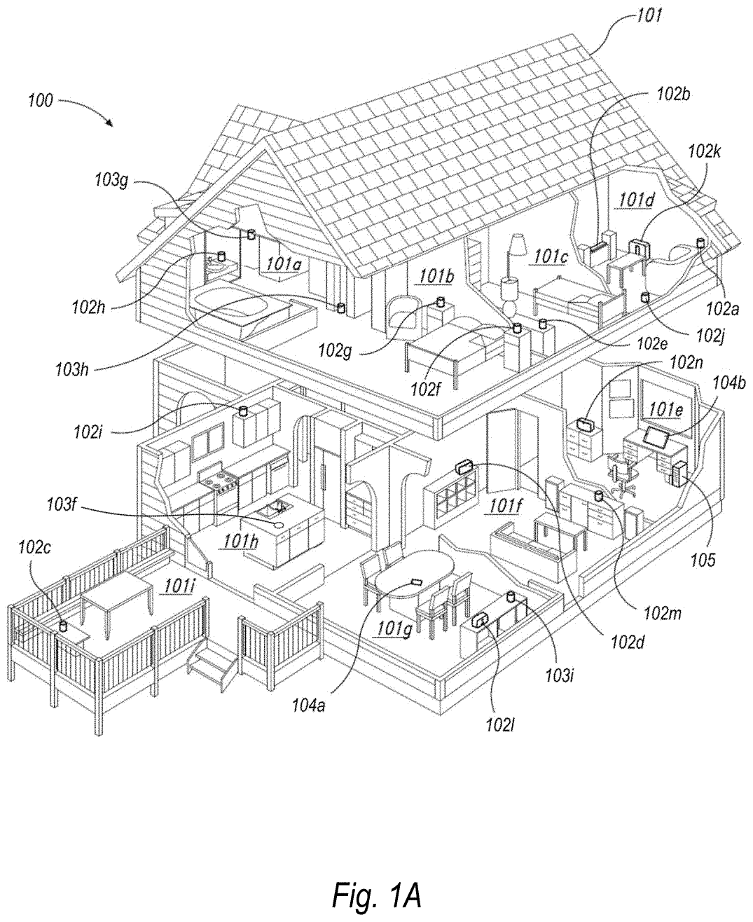

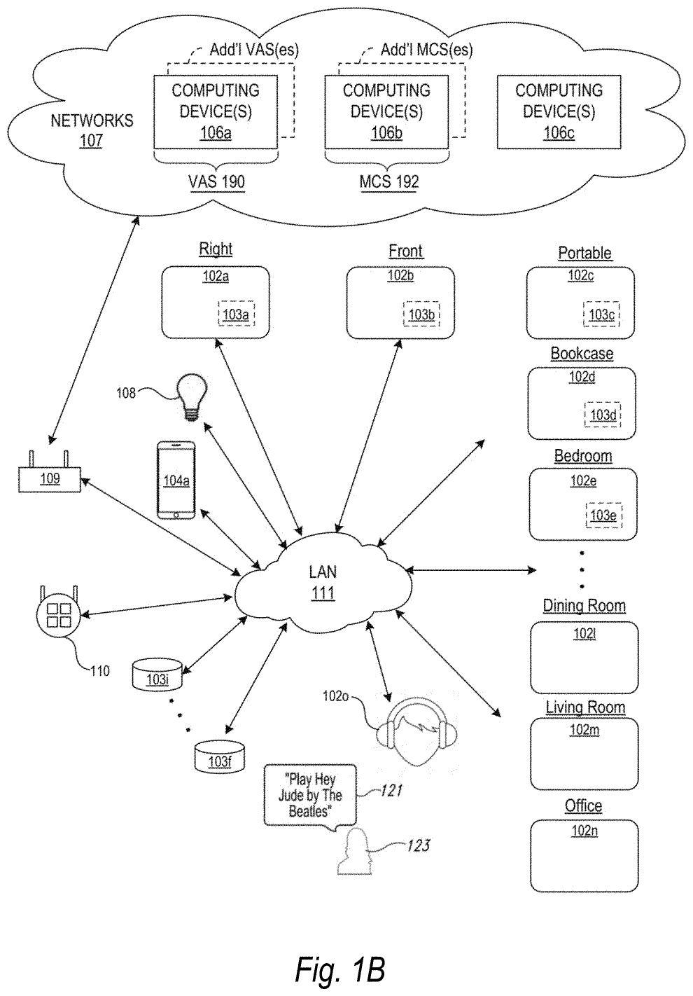

The drawings are for purposes of illustrating example embodiments, but it should be understood that the inventions are not limited to the arrangements and instrumentality shown in the drawings. In the drawings, identical reference numbers identify at least generally similar elements. To facilitate the discussion of any particular element, the most significant digit or digits of any reference number refers to the Figure in which that element is first introduced. For example, element 103a is first introduced and discussed with reference to FIG. 1A.

### DETAILED DESCRIPTION

### I. Overview

Example techniques described herein involve a media playback system of one or more playback devices that are operable in a plurality of modes. Operating in a given mode may enhance a use case corresponding to the mode. For instance, the plurality of modes may include a foreground mode, which may enhance active listening to the playback device. The plurality of modes may also include a background mode, which may enhance passive listening to the playback device by facilitating other activities during passive listening. In some example implementations, the plurality of modes are non-contemporary; when operating in one mode, the playback device will not be operating in the other modes, and vice versa.

To illustrate, in the background mode, the playback device(s) is configured to facilitate conversation (e.g., between members of a household, or at a social gathering). In an example, an example playback device may enable ducking of audio played back while in the background mode. In particular, the playback device(s) may duck frequencies of the played back audio corresponding to human voice (e.g., 85 to 255 Hz). Such ducking may facilitate conversion in the presence of audio playback by the playback device(s).

In contrast, in the foreground mode, the playback device(s) may be configured to provide a “pure” listening experience. That is, since the user(s) are actively listening, the playback device may disable ducking and/or other features that may have an effect on the user's enjoyment of the audio. At the same time, while in the foreground mode, the playback device may prioritize certain audio over the primary content that the user is listening to. For instance, while one or more playback devices are playing home theater content (e.g., from a HDMI cable using HDMI Audio Return Channel), the playback device(s) may receive a carbon monoxide detection alarm from a smart smoke alarm and play audio corresponding to this alarm over (or instead of) the home theater content.

The plurality of modes may also include a do-not-disturb mode. In the do-not-disturb mode, the playback device(s) are configured to avoid interrupting the user, such as by foregoing audio playback. Example playback devices described herein may be formed into groups for synchronous playback, which may inadvertently cause interruptions. For instance, a user may start playback on their playback device in their living room, forgetting that this playback device is grouped with a playback device in a bedroom (in which another member of the household may be sleeping). Setting a do-not-disturb mode in the bedroom may prevent such an interruption. While in the do-not-disturb mode, some exceptions may be permitted, such as alerts from cloud services (e.g., a doorbell rung alert from a smart doorbell).

The plurality of modes may further include an away mode. A user may set an away mode while they are away from home. In the away mode, the playback device(s) may simulate presence of users in the household by playing back audio content. Further, the playback device(s) may disable alarms and scheduled playback, as the user is not home to hear the alarm or enjoy the scheduled playback.

Yet further, in the away mode, the playback device(s) may be configured to enhance home security. For instance, the playback device(s) may disable voice assistant(s) configured on the media playback system to prevent use of these systems (and their private data) by uninvited guests. Yet further, the playback device(s) may enable intrusion detection (e.g., glass break sensing) on one or more microphones (that might otherwise be used with the voice assistant(s)).

In example implementations, the playback device(s) may switch between the various operating modes autonomously based on detecting occurrence of trigger conditions corresponding to the various modes. Example trigger conditions include changes to playback device state driven by user input. For instance, example trigger conditions corresponding to the foreground mode may include switching from an idle state to a playing state, or making a volume adjustment. Notably, such user input is not provided to explicitly change mode, but to explicitly change how the playback device is otherwise operating.

Other example trigger conditions may include conditions not driven by user input. For instance, a period of inactivity (i.e., no user input) elapsing may be configured as occurrence of a first trigger condition corresponding to the background mode. As another example, a shift from explicitly-selected audio content (e.g., a user-selected playlist or album) to implicitly-selected audio content (e.g., auto-playing tracks following explicitly-selected audio content) may be configured as occurrence of a second trigger condition corresponding to the background mode.

The media playback system may implement an event/subscriber model. In such a model, trigger conditions are events that are generated when the trigger condition occurs. For instance, a playback device may subscribe to one or more namespaces (e.g., a mode trigger namespace) that define trigger conditions. When the media playback system detects occurrence of a trigger condition, the media playback system may generate an event corresponding to the trigger condition, which is propagated to the subscribers of the namespace. Ultimately, when the subscriber is notified of an event corresponding to the occurrence of a trigger condition, the subscriber may take appropriate action, if necessary (e.g., to change modes if the trigger condition corresponds to a different mode than the subscriber is currently operating in).

Trigger condition occurrence and event detection may be local to a playback device. For instance, a first component of a playback device (e.g., a state daemon) may maintain state information representing various states of the playback device. A change to one (or more) of these states may cause the first component to generate an event corresponding to occurrence of a first trigger condition. This event may be propagated locally on the playback device to a second component (e.g., to a mode daemon, via an inter-process communication (IPC) mechanism) to cause the second component to take action based on the occurrence of the first trigger condition (i.e., to switch modes, if appropriate).

Additionally, or alternatively, such events may be propagated over a local area network (LAN) to multiple subscribers on the LAN. For instance, a first component on a first playback device (e.g., a state daemon) may generate an event corresponding to a second trigger condition. The event may be propagated locally on the first playback device to a second component of the first playback device, as well as to similar second components of one or more second playback devices in the media playback system. In this manner, trigger conditions occurring through the media playback system may trigger state changes on one or multiple playback devices.

In various examples, the playback device(s) of the media playback system may be configured to detect external conditions within a household or other operating environment, which may be defined as trigger conditions for the various modes. For instance, a voice activity detector on a playback device in a kitchen zone may detect voice activity in the kitchen zone, which may trigger a mode change to a background mode for example. Yet further, the playback device(s) of the media playback system may receive contextual information from other devices. For instance, a smart watch may send contextual data indicating that a person is sleeping in a given zone, which may trigger a do-not-disturb mode on playback devices in that zone.

Alternatively, the playback device(s) may utilize a manual setting to switch between operating modes (perhaps in addition to autonomous triggering). For instance, a user may set or schedule an away mode before leaving for a work trip or vacation using a graphical user interface (GUI) on controller device or a voice user interface (VUI) with a voice assistant. As another example, a user may set a do-not-disturb mode before a conference call while working from home. Many examples are possible.

As noted above, example techniques relate to playback devices that are operable in a plurality of modes. An example implementation involves a media playback system comprising a first playback device operable in a plurality of noncontemporary modes comprising a foreground mode and a background mode, wherein the first playback device comprises at least one microphone, a network interface, at least one processor and data storage including instructions that are executable by the at least one processor such that the first playback device is configured to: play back audio via one or more speakers while operating in the background mode, wherein the first playback device is configured to duck frequencies of the audio corresponding to human voice when operating in the background mode; detect occurrence of a first trigger condition corresponding to the foreground mode; based on detecting the occurrence of the first trigger condition corresponding to the foreground mode, switch the first playback device from operating in the background mode to operating in the foreground mode; and play back the audio via one or more speakers while operating in the foreground mode, wherein the first playback device is configured to forego ducking when operating in the background mode.

While some embodiments described herein may refer to functions performed by given actors, such as “users” and/or other entities, it should be understood that this description is for purposes of explanation only. The claims should not be interpreted to require action by any such example actor unless explicitly required by the language of the claims themselves.

Moreover, some functions are described herein as being performed “based on” or “in response to” another element or function. “Based on” should be understood that one element or function is related to another function or element. “In response to” should be understood that one element or function is a necessary result of another function or element. For the sake of brevity, functions are generally described as being based on another function when a functional link exists; however, such disclosure should be understood as disclosing either type of functional relationship.

### II. Example Operation Environment

FIGS. 1A and 1B illustrate an example configuration of a media playback system 100 (or “MPS 100”) in which one or more embodiments disclosed herein may be implemented. Referring first to FIG. 1A, the MPS 100 as shown is associated with an example home environment having a plurality of rooms and spaces, which may be collectively referred to as a “home environment,” “smart home,” or “environment 101.” The environment 101 comprises a household having several rooms, spaces, and/or playback zones, including a master bathroom 101a, a master bedroom 101b, (referred to herein as “Nick's Room”), a second bedroom 101c, a family room or den 101d, an office 101e, a living room 101f, a dining room 101g, a kitchen 101h, and an outdoor patio 101i. While certain embodiments and examples are described below in the context of a home environment, the technologies described herein may be implemented in other types of environments. In some embodiments, for example, the MPS 100 can be implemented in one or more commercial settings (e.g., a restaurant, mall, airport, hotel, a retail or other store), one or more vehicles (e.g., a sports utility vehicle, bus, car, a ship, a boat, an airplane), multiple environments (e.g., a combination of home and vehicle environments), and/or another suitable environment where multi-zone audio may be desirable.

Within these rooms and spaces, the MPS 100 includes one or more computing devices. Referring to FIGS. 1A and 1B together, such computing devices can include playback devices 102 (identified individually as playback devices 102a-102n), network microphone devices 103 (identified individually as “NMDs” 103a-102i), and controller devices 104a and 104b (collectively “controller devices 104”). Referring to FIG. 1B, the home environment may include additional and/or other computing devices, including local network devices, such as one or more smart illumination devices 108 (FIG. 1B), a smart thermostat 110, and a local computing device 105 (FIG. 1A).

With reference still to FIG. 1B, the various playback, network microphone, and controller devices 102, 103, and 104 and/or other network devices of the MPS 100 may be coupled to one another via point-to-point connections and/or over other connections, which may be wired and/or wireless, via a network 111, such as a LAN including a network router 109. For example, the playback device 102j in the Den 101d (FIG. 1A), which may be designated as the “Left” device, may have a point-to-point connection with the playback device 102a, which is also in the Den 101d and may be designated as the “Right” device. In a related embodiment, the Left playback device 102j may communicate with other network devices, such as the playback device 102b, which may be designated as the “Front” device, via a point-to-point connection and/or other connections via the NETWORK 111.

As further shown in FIG. 1B, the MPS 100 may be coupled to one or more remote computing devices 106 via a wide area network (“WAN”) (i.e., the Internet), labeled here as the networks 107. In some embodiments, each remote computing device 106 may take the form of one or more cloud servers. The remote computing devices 106 may be configured to interact with computing devices in the environment 101 in various ways. For example, the remote computing devices 106 may be configured to facilitate streaming and/or controlling playback of media content, such as audio, in the home environment 101.

In some implementations, the various playback devices, NMDs, and/or controller devices 102-104 may be communicatively coupled to at least one remote computing device associated with a VAS and at least one remote computing device associated with a media content service (“MCS”). For instance, in the illustrated example of FIG. 1B, remote computing devices 106 are associated with a VAS 190 and remote computing devices 106b are associated with an MCS 192. Although only a single VAS 190 and a single MCS 192 are shown in the example of FIG. 1B for purposes of clarity, the MPS 100 may be coupled to multiple, different VASes and/or MCSes. In some implementations, VASes may be operated by one or more of AMAZON, GOOGLE, APPLE, MICROSOFT, SONOS or other voice assistant providers. In some implementations, MCSes may be operated by one or more of SPOTIFY, PANDORA, AMAZON MUSIC, or other media content services.

As further shown in FIG. 1B, the remote computing devices 106 further include remote computing device 106c configured to perform certain operations, such as remotely facilitating media playback functions, managing device and system status information, directing communications between the devices of the MPS 100 and one or multiple VASes and/or MCSes, among other operations. In one example, the remote computing devices 106c provide cloud servers for one or more SONOS Wireless HiFi Systems.

In various implementations, one or more of the playback devices 102 may take the form of or include an on-board (e.g., integrated) network microphone device. For example, the playback devices 102a—e include or are otherwise equipped with corresponding NMDs 103a—e, respectively. A playback device that includes or is equipped with an NMD may be referred to herein interchangeably as a playback device or an NMD unless indicated otherwise in the description. In some cases, one or more of the NMDs 103 may be a stand-alone device. For example, the NMDs 103f and 103g may be stand-alone devices. A stand-alone NMD may omit components and/or functionality that is typically included in a playback device, such as a speaker or related electronics. For instance, in such cases, a stand-alone NMD may not produce audio output or may produce limited audio output (e.g., relatively low-quality audio output).

The various playback and network microphone devices 102 and 103 of the MPS 100 may each be associated with a unique name, which may be assigned to the respective devices by a user, such as during setup of one or more of these devices. For instance, as shown in the illustrated example of FIG. 1B, a user may assign the name “Bookcase” to playback device 102d because it is physically situated on a bookcase. Similarly, the NMD 103f may be assigned the named “Island” because it is physically situated on an island countertop in the kitchen 101h (FIG. 1A). Some playback devices may be assigned names according to a zone or room, such as the playback devices 102e, 102l, 102m, and 102n, which are named “Bedroom,” “Dining Room,” “Living Room,” and “Office,” respectively. Further, certain playback devices may have functionally descriptive names. For example, the playback devices 102a and 102b are assigned the names “Right” and “Front,” respectively, because these two devices are configured to provide specific audio channels during media playback in the zone of the Den 101d (FIG. 1A). The playback device 102c in the Patio may be named portable because it is battery-powered and/or readily transportable to different areas of the environment 101. Other naming conventions are possible.

As discussed above, an NMD may detect and process sound from its environment, such as sound that includes background noise mixed with speech spoken by a person in the NMD's vicinity. For example, as sounds are detected by the NMD in the environment, the NMD may process the detected sound to determine if the sound includes speech that contains voice input intended for the NMD and ultimately a particular VAS. For example, the NMD may identify whether speech includes a wake word associated with a particular VAS.

In the illustrated example of FIG. 1B, the NMDs 103 are configured to interact with the VAS 190 over a network via the network 111 and the router 109. Interactions with the VAS 190 may be initiated, for example, when an NMD identifies in the detected sound a potential wake word. The identification causes a wake-word event, which in turn causes the NMD to begin transmitting detected-sound data to the VAS 190. In some implementations, the various local network devices 102-105 (FIG. 1A) and/or remote computing devices 106c of the MPS 100 may exchange various feedback, information, instructions, and/or related data with the remote computing devices associated with the selected VAS. Such exchanges may be related to or independent of transmitted messages containing voice inputs. In some embodiments, the remote computing device(s) and the MPS 100 may exchange data via communication paths as described herein and/or using a metadata exchange channel as described in U.S. application Ser. No. 15/438,749 filed Feb. 21, 2017, and titled “Voice Control of a Media Playback System,” which is herein incorporated by reference in its entirety.

Upon receiving the stream of sound data, the VAS 190 determines if there is voice input in the streamed data from the NMD, and if so the VAS 190 will also determine an underlying intent in the voice input. The VAS 190 may next transmit a response back to the MPS 100, which can include transmitting the response directly to the NMD that caused the wake-word event. The response is typically based on the intent that the VAS 190 determined was present in the voice input. As an example, in response to the VAS 190 receiving a voice input with an utterance to “Play Hey Jude by The Beatles,” the VAS 190 may determine that the underlying intent of the voice input is to initiate playback and further determine that intent of the voice input is to play the particular song “Hey Jude.” After these determinations, the VAS 190 may transmit a command to a particular MCS 192 to retrieve content (i.e., the song “Hey Jude”), and that MCS 192, in turn, provides (e.g., streams) this content directly to the MPS 100 or indirectly via the VAS 190. In some implementations, the VAS 190 may transmit to the MPS 100 a command that causes the MPS 100 itself to retrieve the content from the MCS 192.

In certain implementations, NMDs may facilitate arbitration amongst one another when voice input is identified in speech detected by two or more NMDs located within proximity of one another. For example, the NMD-equipped playback device 102d in the environment 101 (FIG. 1A) is in relatively close proximity to the NMD-equipped Living Room playback device 102m, and both devices 102d and 102m may at least sometimes detect the same sound. In such cases, this may require arbitration as to which device is ultimately responsible for providing detected-sound data to the remote VAS. Examples of arbitrating between NMDs may be found, for example, in previously referenced U.S. application Ser. No. 15/438,749.

In certain implementations, an NMD may be assigned to, or otherwise associated with, a designated or default playback device that may not include an NMD. For example, the Island NMD 103f in the kitchen 101h (FIG. 1A) may be assigned to the dining room playback device 102l, which is in relatively close proximity to the Island NMD 103f. In practice, an NMD may direct an assigned playback device to play audio in response to a remote VAS receiving a voice input from the NMD to play the audio, which the NMD might have sent to the VAS in response to a user speaking a command to play a certain song, album, playlist, etc. Additional details regarding assigning NMDs and playback devices as designated or default devices may be found, for example, in previously referenced U.S. patent application No.

Further aspects relating to the different components of the example MPS 100 and how the different components may interact to provide a user with a media experience may be found in the following sections. While discussions herein may generally refer to the example MPS 100, technologies described herein are not limited to applications within, among other things, the home environment described above. For instance, the technologies described herein may be useful in other home environment configurations comprising more or fewer of any of the playback, network microphone, and/or controller devices 102-104. For example, the technologies herein may be utilized within an environment having a single playback device 102 and/or a single NMD 103. In some examples of such cases, the NETWORK 111 (FIG. 1B) may be eliminated and the single playback device 102 and/or the single NMD 103 may communicate directly with the remote computing devices 106-d. In some embodiments, a telecommunication network (e.g., an LTE network, a 5G network, etc.) may communicate with the various playback, network microphone, and/or controller devices 102-104 independent of a LAN.

a. Example Playback & Network Microphone Devices

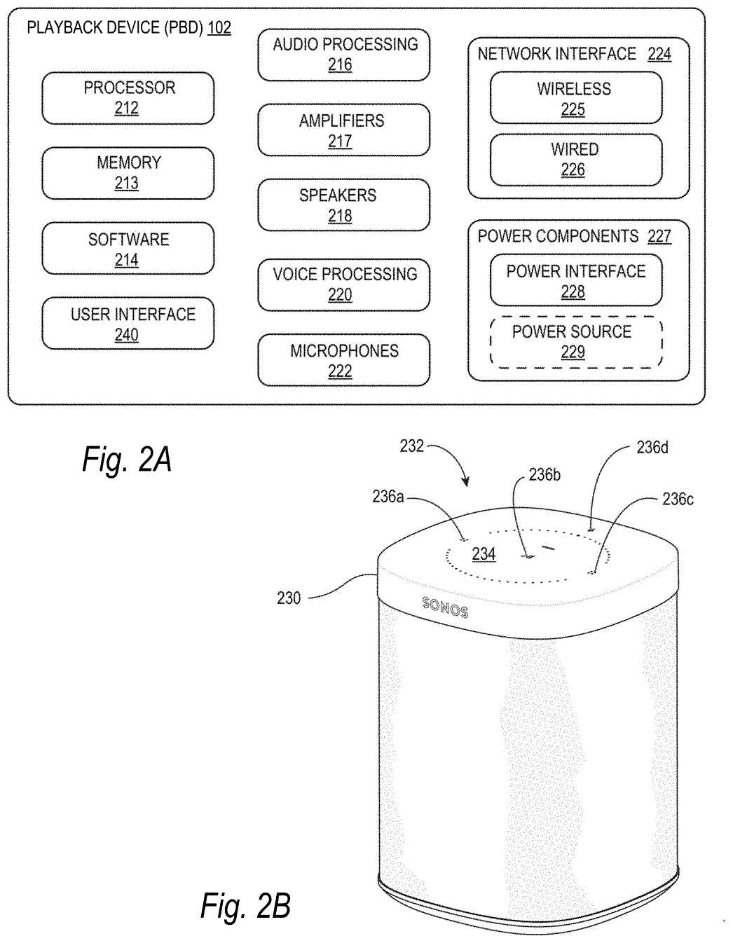

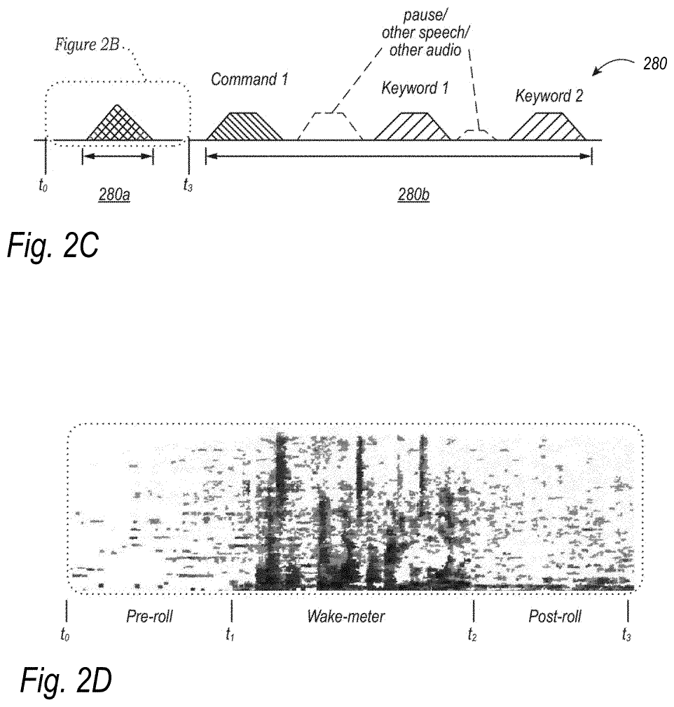

FIG. 2A is a functional block diagram illustrating certain aspects of one of the playback devices 102 of the MPS 100 of FIGS. 1A and 1B. As shown, the playback device 102 includes various components, each of which is discussed in further detail below, and the various components of the playback device 102 may be operably coupled to one another via a system bus, communication network, or some other connection mechanism. In the illustrated example of FIG. 2A, the playback device 102 may be referred to as an “NMD-equipped” playback device because it includes components that support the functionality of an NMD, such as one of the NMDs 103 shown in FIG. 1A.

As shown, the playback device 102 includes at least one processor 212, which may be a clock-driven computing component configured to process input data according to instructions stored in memory 213. The memory 213 may be a tangible, non-transitory, computer-readable medium configured to store instructions that are executable by the processor 212. For example, the memory 213 may be data storage that can be loaded with software code 214 that is executable by the processor 212 to achieve certain functions.

In one example, these functions may involve the playback device 102 retrieving audio data from an audio source, which may be another playback device. In another example, the functions may involve the playback device 102 sending audio data, detected-sound data (e.g., corresponding to a voice input), and/or other information to another device on a network via at least one network interface 224. In yet another example, the functions may involve the playback device 102 causing one or more other playback devices to synchronously playback audio with the playback device 102. In yet a further example, the functions may involve the playback device 102 facilitating being paired or otherwise bonded with one or more other playback devices to create a multi-channel audio environment. Numerous other example functions are possible, some of which are discussed below.

As just mentioned, certain functions may involve the playback device 102 synchronizing playback of audio content with one or more other playback devices. During synchronous playback, a listener may not perceive time-delay differences between playback of the audio content by the synchronized playback devices. U.S. Pat. No. 8,234,395 filed on Apr. 4, 2004, and titled “System and method for synchronizing operations among a plurality of independently clocked digital data processing devices,” which is hereby incorporated by reference in its entirety, provides in more detail some examples for audio playback synchronization among playback devices.

To facilitate audio playback, the playback device 102 includes audio processing components 216 that are generally configured to process audio prior to the playback device 102 rendering the audio. In this respect, the audio processing components 216 may include one or more digital-to-analog converters (“DAC”), one or more audio preprocessing components, one or more audio enhancement components, one or more digital signal processors (“DSPs”), and so on. In some implementations, one or more of the audio processing components 216 may be a subcomponent of the processor 212. In operation, the audio processing components 216 receive analog and/or digital audio and process and/or otherwise intentionally alter the audio to produce audio signals for playback.

The produced audio signals may then be provided to one or more audio amplifiers 217 for amplification and playback through one or more speakers 218 operably coupled to the amplifiers 217. The audio amplifiers 217 may include components configured to amplify audio signals to a level for driving one or more of the speakers 218.

In another aspect, the software code 214 configures the playback device 102 to be operable in a plurality of non contemporary room sound modes. In each mode, the playback device 102 may adopt certain settings and/or configurations in accordance with the room sound mode. Further, the software code 214 may be configured to detect occurrence of various triggers corresponding to one of more of the room sounds, and responsively switch the first playback device from operating in one mode to operating in another mode. Further details related to the room sound modes are described in connection with section III below.

Each of the speakers 218 may include an individual transducer (e.g., a “driver”) or the speakers 218 may include a complete speaker system involving an enclosure with one or more drivers. A particular driver of a speaker 218 may include, for example, a subwoofer (e.g., for low frequencies), a mid-range driver (e.g., for middle frequencies), and/or a tweeter (e.g., for high frequencies). In some cases, a transducer may be driven by an individual corresponding audio amplifier of the audio amplifiers 217. In some implementations, a playback device may not include the speakers 218, but instead may include a speaker interface for connecting the playback device to external speakers. In certain embodiments, a playback device may include neither the speakers 218 nor the audio amplifiers 217, but instead may include an audio interface (not shown) for connecting the playback device to an external audio amplifier or audio-visual receiver.

In addition to producing audio signals for playback by the playback device 102, the audio processing components 216 may be configured to process audio to be sent to one or more other playback devices, via the network interface 224, for playback. In example scenarios, audio content to be processed and/or played back by the playback device 102 may be received from an external source, such as via an audio line-in interface (e.g., an auto-detecting 3.5 mm audio line-in connection) of the playback device 102 (not shown) or via the network interface 224, as described below.

As shown, the at least one network interface 224, may take the form of one or more wireless interfaces 225 and/or one or more wired interfaces 226. A wireless interface may provide network interface functions for the playback device 102 to wirelessly communicate with other devices (e.g., other playback device(s), NMD(s), and/or controller device(s)) in accordance with a communication protocol (e.g., any wireless standard including IEEE 802.11a, 802.11b, 802.11g, 802.11n, 802.11ac, 802.15, 4G mobile communication standard, and so on). A wired interface may provide network interface functions for the playback device 102 to communicate over a wired connection with other devices in accordance with a communication protocol (e.g., IEEE 802.3). While the network interface 224 shown in FIG. 2A include both wired and wireless interfaces, the playback device 102 may in some implementations include only wireless interface(s) or only wired interface(s).

In general, the network interface 224 facilitates data flow between the playback device 102 and one or more other devices on a data network. For instance, the playback device 102 may be configured to receive audio content over the data network from one or more other playback devices, network devices within a LAN, and/or audio content sources over a WAN, such as the Internet. In one example, the audio content and other signals transmitted and received by the playback device 102 may be transmitted in the form of digital packet data comprising an Internet Protocol (IP)-based source address and IP-based destination addresses. In such a case, the network interface 224 may be configured to parse the digital packet data such that the data destined for the playback device 102 is properly received and processed by the playback device 102.

As shown in FIG. 2A, the playback device 102 also includes voice processing components 220 that are operably coupled to one or more microphones 222. The microphones 222 are configured to detect sound (i.e., acoustic waves) in the environment of the playback device 102, which is then provided to the voice processing components 220. More specifically, each microphone 222 is configured to detect sound and convert the sound into a digital or analog signal representative of the detected sound, which can then cause the voice processing component 220 to perform various functions based on the detected sound, as described in greater detail below. In one implementation, the microphones 222 are arranged as an array of microphones (e.g., an array of six microphones). In some implementations, the playback device 102 includes more than six microphones (e.g., eight microphones or twelve microphones) or fewer than six microphones (e.g., four microphones, two microphones, or a single microphones).

In operation, the voice-processing components 220 are generally configured to detect and process sound received via the microphones 222, identify potential voice input in the detected sound, and extract detected-sound data to enable a VAS, such as the VAS 190 (FIG. 1B), to process voice input identified in the detected-sound data. The voice processing components 220 may include one or more analog-to-digital converters, an acoustic echo canceller (“AEC”), a spatial processor (e.g., one or more multi-channel Wiener filters, one or more other filters, and/or one or more beam former components), one or more buffers (e.g., one or more circular buffers), one or more wake-word engines, one or more voice extractors, and/or one or more speech processing components (e.g., components configured to recognize a voice of a particular user or a particular set of users associated with a household), among other example voice processing components. In example implementations, the voice processing components 220 may include or otherwise take the form of one or more DSPs or one or more modules of a DSP. In this respect, certain voice processing components 220 may be configured with particular parameters (e.g., gain and/or spectral parameters) that may be modified or otherwise tuned to achieve particular functions. In some implementations, one or more of the voice processing components 220 may be a subcomponent of the processor 212.

As further shown in FIG. 2A, the playback device 102 also includes power components 227. The power components 227 include at least an external power source interface 228, which may be coupled to a power source (not shown) via a power cable or the like that physically connects the playback device 102 to an electrical outlet or some other external power source. Other power components may include, for example, transformers, converters, and like components configured to format electrical power.

In some implementations, the power components 227 of the playback device 102 may additionally include an internal power source 229 (e.g., one or more batteries) configured to power the playback device 102 without a physical connection to an external power source. When equipped with the internal power source 229, the playback device 102 may operate independent of an external power source. In some such implementations, the external power source interface 228 may be configured to facilitate charging the internal power source 229. As discussed before, a playback device comprising an internal power source may be referred to herein as a “portable playback device.” On the other hand, a playback device that operates using an external power source may be referred to herein as a “stationary playback device,” although such a device may in fact be moved around a home or other environment.

The playback device 102 further includes a user interface 240 that may facilitate user interactions independent of or in conjunction with user interactions facilitated by one or more of the controller devices 104. In various embodiments, the user interface 240 includes one or more physical buttons and/or supports graphical interfaces provided on touch sensitive screen(s) and/or surface(s), among other possibilities, for a user to directly provide input. The user interface 240 may further include one or more of lights (e.g., LEDs) and the speakers to provide visual and/or audio feedback to a user.

As an illustrative example, FIG. 2B shows an example housing 230 of the playback device 102 that includes a user interface in the form of a control area 232 at a top portion 234 of the housing 230. The control area 232 includes buttons 236a-c for controlling audio playback, volume level, and other functions. The control area 232 also includes a button 236d for toggling the microphones 222 to either an on state or an off state.

As further shown in FIG. 2B, the control area 232 is at least partially surrounded by apertures formed in the top portion 234 of the housing 230 through which the microphones 222 (not visible in FIG. 2B) receive the sound in the environment of the playback device 102. The microphones 222 may be arranged in various positions along and/or within the top portion 234 or other areas of the housing 230 so as to detect sound from one or more directions relative to the playback device 102.

By way of illustration, SONOS, Inc. presently offers (or has offered) for sale certain playback devices that may implement certain of the embodiments disclosed herein, including a “PLAY:1,” “PLAY:3,” “PLAY:5,” “PLAYBAR,” “CONNECT:AMP,” “PLAYBASE,” “BEAM,” “CONNECT,” and “SUB.” Any other past, present, and/or future playback devices may additionally or alternatively be used to implement the playback devices of example embodiments disclosed herein. Additionally, it should be understood that a playback device is not limited to the examples illustrated in FIGS. 2A or 2B or to the SONOS product offerings. For example, a playback device may include, or otherwise take the form of, a wired or wireless headphone set, which may operate as a part of the MPS 100 via a network interface or the like. In another example, a playback device may include or interact with a docking station for personal mobile media playback devices. In yet another example, a playback device may be integral to another device or component such as a television, a lighting fixture, or some other device for indoor or outdoor use.

FIG. 2C is a diagram of an example voice input 280 that may be processed by an NMD or an NMD-equipped playback device. The voice input 280 may include a keyword portion 280a and an utterance portion 280b. The keyword portion 280a may include a wake word or a command keyword. In the case of a wake word, the keyword portion 280a corresponds to detected sound that caused a wake-word The utterance portion 280b corresponds to detected sound that potentially comprises a user request following the keyword portion 280a. An utterance portion 280b can be processed to identify the presence of any words in detected-sound data by the NMD in response to the event caused by the keyword portion 280a. In various implementations, an underlying intent can be determined based on the words in the utterance portion 280b. In certain implementations, an underlying intent can also be based or at least partially based on certain words in the keyword portion 280a, such as when keyword portion includes a command keyword. In any case, the words may correspond to one or more commands, as well as a certain command and certain keywords. A keyword in the voice utterance portion 280b may be, for example, a word identifying a particular device or group in the MPS 100. For instance, in the illustrated example, the keywords in the voice utterance portion 280b may be one or more words identifying one or more zones in which the music is to be played, such as the Living Room and the Dining Room (FIG. 1A). In some cases, the utterance portion 280b may include additional information, such as detected pauses (e.g., periods of non-speech) between words spoken by a user, as shown in FIG. 2C. The pauses may demarcate the locations of separate commands, keywords, or other information spoke by the user within the utterance portion 280b.

Based on certain command criteria, the NMD and/or a remote VAS may take actions as a result of identifying one or more commands in the voice input. Command criteria may be based on the inclusion of certain keywords within the voice input, among other possibilities. Additionally, or alternatively, command criteria for commands may involve identification of one or more control-state and/or zone-state variables in conjunction with identification of one or more particular commands. Control-state variables may include, for example, indicators identifying a level of volume, a queue associated with one or more devices, and playback state, such as whether devices are playing a queue, paused, etc. Zone-state variables may include, for example, indicators identifying which, if any, zone players are grouped.

In some implementations, the MPS 100 is configured to temporarily reduce the volume of audio content that it is playing upon detecting a certain keyword, such as a wake word, in the keyword portion 280a. The MPS 100 may restore the volume after processing the voice input 280. Such a process can be referred to as ducking, examples of which are disclosed in U.S. patent application Ser. No. 15/438,749, incorporated by reference herein in its entirety.

FIG. 2D shows an example sound specimen. In this example, the sound specimen corresponds to the sound-data stream (e.g., one or more audio frames) associated with a spotted wake word or command keyword in the keyword portion 280a of FIG. 2A. As illustrated, the example sound specimen comprises sound detected in an NMD's environment (i) immediately before a wake or command word was spoken, which may be referred to as a pre-roll portion (between times t₀ and t₁), (ii) while a wake or command word was spoken, which may be referred to as a wake-meter portion (between times t₁ and t₂), and/or (iii) after the wake or command word was spoken, which may be referred to as a post-roll portion (between times t₂ and t₃). Other sound specimens are also possible. In various implementations, aspects of the sound specimen can be evaluated according to an acoustic model which aims to map mels/spectral features to phonemes in a given language model for further processing. For example, automatic speech recognition (ASR) may include such mapping for command-keyword detection. Wake-word detection engines, by contrast, may be precisely tuned to identify a specific wake-word, and a downstream action of invoking a VAS (e.g., by targeting only nonce words in the voice input processed by the playback device).

ASR for command keyword detection may be tuned to accommodate a wide range of keywords (e.g., 5, 10, 100, 1,000, 10,000 keywords). Command keyword detection, in contrast to wake-word detection, may involve feeding ASR output to an onboard, local NLU which together with the ASR determine when command word events have occurred. In some implementations described below, the local NLU may determine an intent based on one or more other keywords in the ASR output produced by a particular voice input. In these or other implementations, a playback device may act on a detected command keyword event only when the playback devices determines that certain conditions have been met, such as environmental conditions (e.g., low background noise).

The playback device 102 may further include a voice activity detector (VAD), which may be implemented as part of the voice processing components 220. The VAD is configured to detect the presence (or lack thereof) of voice activity in the sound-data stream from the microphones 222. In particular, the VAD may analyze frames corresponding to the pre-roll portion of the voice input 280a (FIG. 2D) with one or more voice detection algorithms to determine whether voice activity was present in the environment in certain time windows prior to a keyword portion of the voice input 280a.

The VAD may utilize any suitable voice activity detection algorithms. Example voice detection algorithms involve determining whether a given frame includes one or more features or qualities that correspond to voice activity, and further determining whether those features or qualities diverge from noise to a given extent (e.g., if a value exceeds a threshold for a given frame). Some example voice detection algorithms involve filtering or otherwise reducing noise in the frames prior to identifying the features or qualities.

In some examples, the VAD may determine whether voice activity is present in the environment based on one or more metrics. For example, the VAD can be configured to distinguish between frames that include voice activity and frames that don't include voice activity. The frames that the VAD determines have voice activity may be caused by speech regardless of whether it near- or far-field. In this example and others, the VAD may determine a count of frames in the voice input 280a that indicate voice activity. If this count exceeds a threshold percentage or number of frames, the VAD may be configured to output a signal or set a state variable indicating that voice activity is present in the environment. Other metrics may be used as well in addition to, or as an alternative to, such a count.

When the VAD detects voice activity in an environment, the VAD may set a state variable in the playback device indicating that voice activity is present. Conversely, when the VAD does not voice activity in an environment, the VAD may set the state variable in the playback device to indicate that voice activity is not present. Changing the state of this state variable may function as a mode trigger condition in some examples.

b. Example Playback Device Configurations

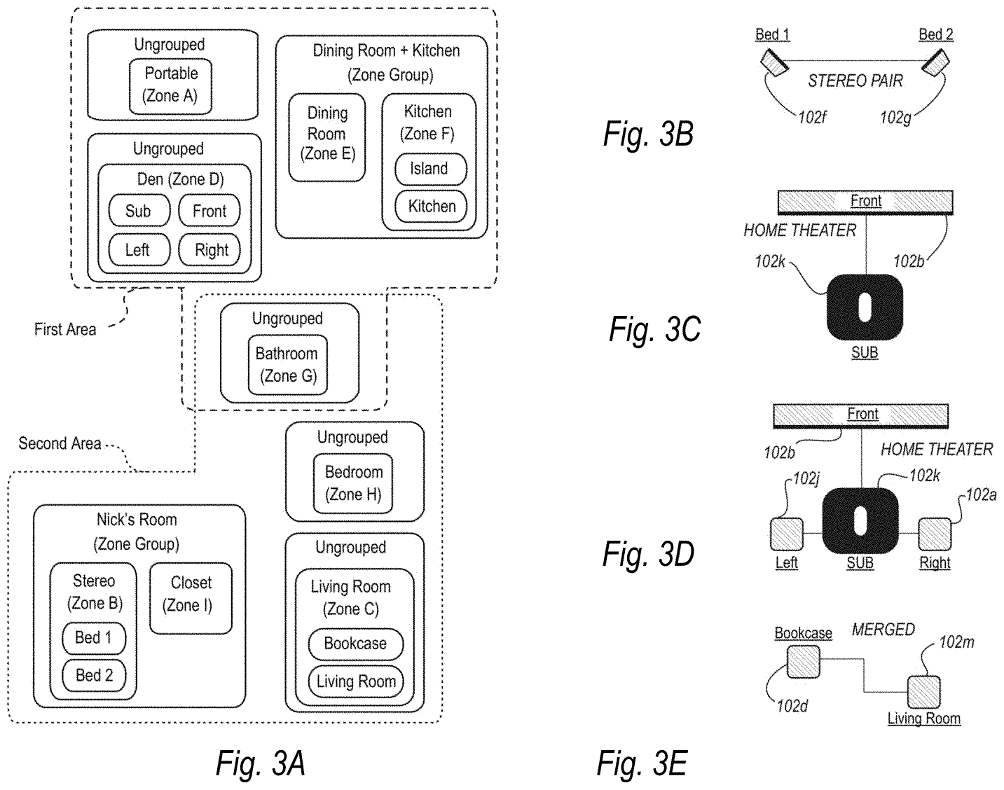

FIGS. 3A-3E show example configurations of playback devices. Referring first to FIG. 3A, in some example instances, a single playback device may belong to a zone. For example, the playback device 102c (FIG. 1A) on the Patio may belong to Zone A. In some implementations described below, multiple playback devices may be “bonded” to form a “bonded pair,” which together form a single zone. For example, the playback device 102f (FIG. 1A) named “Bed 1” in FIG. 3A may be bonded to the playback device 102g (FIG. 1A) named “Bed 2” in FIG. 3A to form Zone B. Bonded playback devices may have different playback responsibilities (e.g., channel responsibilities). In another implementation described below, multiple playback devices may be merged to form a single zone. For example, the playback device 102d named “Bookcase” may be merged with the playback device 102m named “Living Room” to form a single Zone C. The merged playback devices 102d and 102m may not be specifically assigned different playback responsibilities. That is, the merged playback devices 102d and 102m may, aside from playing audio content in synchrony, each play audio content as they would if they were not merged.

For purposes of control, each zone in the MPS 100 may be represented as a single user interface (“UI”) entity. For example, as displayed by the controller devices 104, Zone A may be provided as a single entity named “Portable,” Zone B may be provided as a single entity named “Stereo,” and Zone C may be provided as a single entity named “Living Room.”

In various embodiments, a zone may take on the name of one of the playback devices belonging to the zone. For example, Zone C may take on the name of the Living Room device 102m (as shown). In another example, Zone C may instead take on the name of the Bookcase device 102d. In a further example, Zone C may take on a name that is some combination of the Bookcase device 102d and Living Room device 102m. The name that is chosen may be selected by a user via inputs at a controller device 104. In some embodiments, a zone may be given a name that is different than the device(s) belonging to the zone. For example, Zone B in FIG. 3A is named “Stereo” but none of the devices in Zone B have this name. In one aspect, Zone B is a single UI entity representing a single device named “Stereo,” composed of constituent devices “Bed 1” and “Bed 2.” In one implementation, the Bed 1 device may be playback device 102f in the master bedroom 101b (FIG. 1A) and the Bed 2 device may be the playback device 102g also in the master bedroom 101b (FIG. 1A).

As noted above, playback devices that are bonded may have different playback responsibilities, such as playback responsibilities for certain audio channels. For example, as shown in FIG. 3B, the Bed 1 and Bed 2 devices 102f and 102g may be bonded so as to produce or enhance a stereo effect of audio content. In this example, the Bed 1 playback device 102f may be configured to play a left channel audio component, while the Bed 2 playback device 102g may be configured to play a right channel audio component. In some implementations, such stereo bonding may be referred to as “pairing.”

Additionally, playback devices that are configured to be bonded may have additional and/or different respective speaker drivers. As shown in FIG. 3C, the playback device 102b named “Front” may be bonded with the playback device 102k named “SUB.” The Front device 102b may render a range of mid to high frequencies, and the SUB device 102k may render low frequencies as, for example, a subwoofer. When unbonded, the Front device 102b may be configured to render a full range of frequencies. As another example, FIG. 3D shows the Front and SUB devices 102b and 102k further bonded with Right and Left playback devices 102a and 102j, respectively. In some implementations, the Right and Left devices 102a and 102j may form surround or “satellite” channels of a home theater system. The bonded playback devices 102a, 102b, 102j, and 102k may form a single Zone D (FIG. 3A).

In some implementations, playback devices may also be “merged.” In contrast to certain bonded playback devices, playback devices that are merged may not have assigned playback responsibilities, but may each render the full range of audio content that each respective playback device is capable of. Nevertheless, merged devices may be represented as a single UI entity (i.e., a zone, as discussed above). For instance, FIG. 3E shows the playback devices 102d and 102m in the Living Room merged, which would result in these devices being represented by the single UI entity of Zone C. In one embodiment, the playback devices 102d and 102m may playback audio in synchrony, during which each outputs the full range of audio content that each respective playback device 102d and 102m is capable of rendering.

In some embodiments, a stand-alone NMD may be in a zone by itself. For example, the NMD 103h from FIG. 1A is named “Closet” and forms Zone I in FIG. 3A. An NMD may also be bonded or merged with another device so as to form a zone. For example, the NMD device 103f named “Island” may be bonded with the playback device 102i Kitchen, which together form Zone F, which is also named “Kitchen.” Additional details regarding assigning NMDs and playback devices as designated or default devices may be found, for example, in previously referenced U.S. patent application Ser. No. 15/438,749. In some embodiments, a stand-alone NMD may not be assigned to a zone.

Zones of individual, bonded, and/or merged devices may be arranged to form a set of playback devices that playback audio in synchrony. Such a set of playback devices may be referred to as a “group,” “zone group,” “synchrony group,” or “playback group.” In response to inputs provided via a controller device 104, playback devices may be dynamically grouped and ungrouped to form new or different groups that synchronously play back audio content. For example, referring to FIG. 3A, Zone A may be grouped with Zone B to form a zone group that includes the playback devices of the two zones. As another example, Zone A may be grouped with one or more other Zones C-I. The Zones A-I may be grouped and ungrouped in numerous ways. For example, three, four, five, or more (e.g., all) of the Zones A-I may be grouped. When grouped, the zones of individual and/or bonded playback devices may play back audio in synchrony with one another, as described in previously referenced U.S. Pat. No. 8,234,395. Grouped and bonded devices are example types of associations between portable and stationary playback devices that may be caused in response to a trigger event, as discussed above and described in greater detail below.

In various implementations, the zones in an environment may be assigned a particular name, which may be the default name of a zone within a zone group or a combination of the names of the zones within a zone group, such as “Dining Room+Kitchen,” as shown in FIG. 3A. In some embodiments, a zone group may be given a unique name selected by a user, such as “Nick's Room,” as also shown in FIG. 3A. The name “Nick's Room” may be a name chosen by a user over a prior name for the zone group, such as the room name “Master Bedroom.”

Referring back to FIG. 2A, certain data may be stored in the memory 213 as one or more state variables that are periodically updated and used to describe the state of a playback zone, the playback device(s), and/or a zone group associated therewith. The memory 213 may also include the data associated with the state of the other devices of the MPS 100, which may be shared from time to time among the devices so that one or more of the devices have the most recent data associated with the system.

In some embodiments, the memory 213 of the playback device 102 may store instances of various variable types associated with the states. Variables instances may be stored with identifiers (e.g., tags) corresponding to type. For example, certain identifiers may be a first type “al” to identify playback device(s) of a zone, a second type “b1” to identify playback device(s) that may be bonded in the zone, and a third type “c1” to identify a zone group to which the zone may belong. As a related example, in FIG. 1A, identifiers associated with the Patio may indicate that the Patio is the only playback device of a particular zone and not in a zone group. Identifiers associated with the Living Room may indicate that the Living Room is not grouped with other zones but includes bonded playback devices 102a, 102b, 102j, and 102k. Identifiers associated with the Dining Room may indicate that the Dining Room is part of Dining Room+Kitchen group and that devices 103f and 102i are bonded. Identifiers associated with the Kitchen may indicate the same or similar information by virtue of the Kitchen being part of the Dining Room+Kitchen zone group. Other example zone variables and identifiers are described below.

In yet another example, the MPS 100 may include variables or identifiers representing other associations of zones and zone groups, such as identifiers associated with Areas, as shown in FIG. 3A. An Area may involve a cluster of zone groups and/or zones not within a zone group. For instance, FIG. 3A shows a first area named “First Area” and a second area named “Second Area.” The First Area includes zones and zone groups of the Patio, Den, Dining Room, Kitchen, and Bathroom. The Second Area includes zones and zone groups of the Bathroom, Nick's Room, Bedroom, and Living Room. In one aspect, an Area may be used to invoke a cluster of zone groups and/or zones that share one or more zones and/or zone groups of another cluster. In this respect, such an Area differs from a zone group, which does not share a zone with another zone group. Further examples of techniques for implementing Areas may be found, for example, in U.S. application Ser. No. 15/682,506 filed Aug. 21, 2017 and titled “Room Association Based on Name,” and U.S. Pat. No. 8,483,853 filed Sep. 11, 2007, and titled “Controlling and manipulating groupings in a multi-zone media system.” Each of these applications is incorporated herein by reference in its entirety.

The memory 213 may be further configured to store other data. Such data may pertain to audio sources accessible by the playback device 102 or a playback queue that the playback device (or some other playback device(s)) may be associated with. In embodiments described below, the memory 213 is configured to store a set of command data for selecting a particular VAS when processing voice inputs. During operation, one or more playback zones in the environment of FIG. 1A may each be playing different audio content. For instance, the user may be grilling in the Patio zone and listening to hip hop music being played by the playback device 102c, while another user may be preparing food in the Kitchen zone and listening to classical music being played by the playback device 102i. In another example, a playback zone may play the same audio content in synchrony with another playback zone.

For instance, the user may be in the Office zone where the playback device 102n is playing the same hip-hop music that is being playing by playback device 102c in the Patio zone. In such a case, playback devices 102c and 102n may be playing the hip-hop in synchrony such that the user may seamlessly (or at least substantially seamlessly) enjoy the audio content that is being played out-loud while moving between different playback zones. Synchronization among playback zones may be achieved in a manner similar to that of synchronization among playback devices, as described in previously referenced U.S. Pat. No. 8,234,395.

As suggested above, the zone configurations of the MPS 100 may be dynamically modified. As such, the MPS 100 may support numerous configurations. For example, if a user physically moves one or more playback devices to or from a zone, the MPS 100 may be reconfigured to accommodate the change(s). For instance, if the user physically moves the playback device 102c from the Patio zone to the Office zone, the Office zone may now include both the playback devices 102c and 102n. In some cases, the user may pair or group the moved playback device 102c with the Office zone and/or rename the players in the Office zone using, for example, one of the controller devices 104 and/or voice input. As another example, if one or more playback devices 102 are moved to a particular space in the home environment that is not already a playback zone, the moved playback device(s) may be renamed or associated with a playback zone for the particular space.

Further, different playback zones of the MPS 100 may be dynamically combined into zone groups or split up into individual playback zones. For example, the Dining Room zone and the Kitchen zone may be combined into a zone group for a dinner party such that playback devices 102i and 102l may render audio content in synchrony. As another example, bonded playback devices in the Den zone may be split into (i) a television zone and (ii) a separate listening zone. The television zone may include the Front playback device 102b. The listening zone may include the Right, Left, and SUB playback devices 102a, 102j, and 102k, which may be grouped, paired, or merged, as described above. Splitting the Den zone in such a manner may allow one user to listen to music in the listening zone in one area of the living room space, and another user to watch the television in another area of the living room space. In a related example, a user may utilize either of the NMD 103a or 103b (FIG. 1B) to control the Den zone before it is separated into the television zone and the listening zone. Once separated, the listening zone may be controlled, for example, by a user in the vicinity of the NMD 103a, and the television zone may be controlled, for example, by a user in the vicinity of the NMD 103b. As described above, however, any of the NMDs 103 may be configured to control the various playback and other devices of the MPS 100.

c. Example Controller Devices

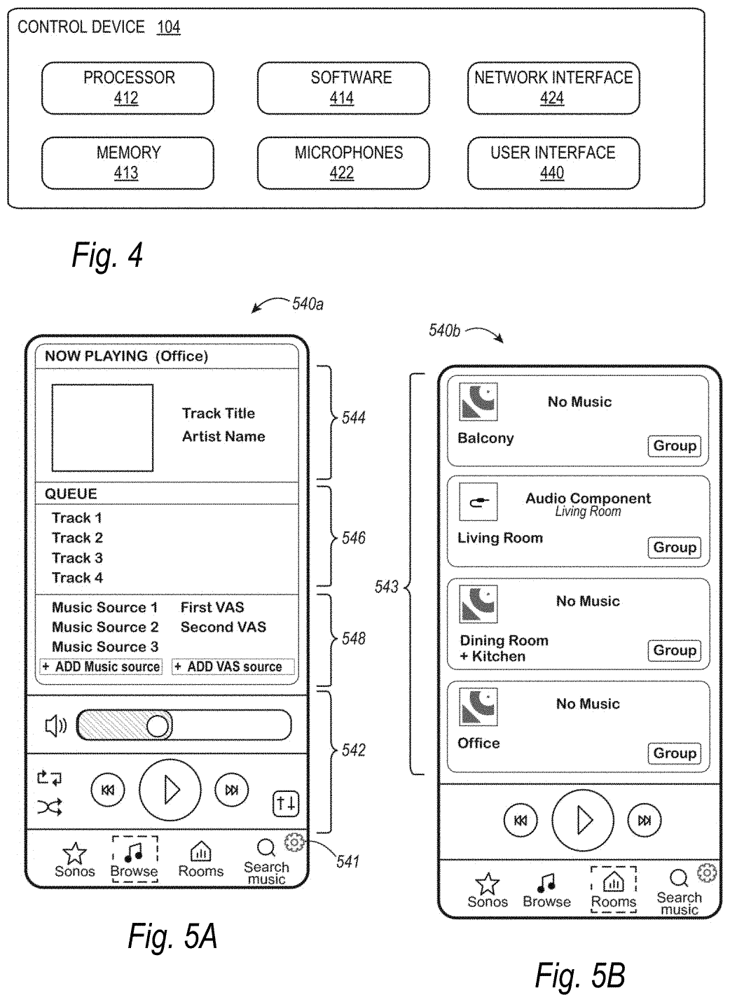

FIG. 4 is a functional block diagram illustrating certain aspects of a selected one of the controller devices 104 of the MPS 100 of FIG. 1A. Such controller devices may also be referred to herein as a “control device” or “controller.” The controller device shown in FIG. 4 may include components that are generally similar to certain components of the network devices described above, such as a processor 412, memory 413 storing program software 414, at least one network interface 424, and one or more microphones 422. In one example, a controller device may be a dedicated controller for the MPS 100. In another example, a controller device may be a network device on which media playback system controller application software may be installed, such as for example, an iPhone™, iPad™ or any other smart phone, tablet, or network device (e.g., a networked computer such as a PC or Mac™).

The memory 413 of the controller device 104 may be configured to store controller application software and other data associated with the MPS 100 and/or a user of the system 100. The memory 413 may be loaded with instructions in software 414 that are executable by the processor 412 to achieve certain functions, such as facilitating user access, control, and/or configuration of the MPS 100. The controller device 104 is configured to communicate with other network devices via the network interface 424, which may take the form of a wireless interface, as described above.

In one example, system information (e.g., such as a state variable) may be communicated between the controller device 104 and other devices via the network interface 424. For instance, the controller device 104 may receive playback zone and zone group configurations in the MPS 100 from a playback device, an NMD, or another network device. Likewise, the controller device 104 may transmit such system information to a playback device or another network device via the network interface 424. In some cases, the other network device may be another controller device.

The controller device 104 may also communicate playback device control commands, such as volume control and audio playback control, to a playback device via the network interface 424. As suggested above, changes to configurations of the MPS 100 may also be performed by a user using the controller device 104. The configuration changes may include adding/removing one or more playback devices to/from a zone, adding/removing one or more zones to/from a zone group, forming a bonded or merged player, separating one or more playback devices from a bonded or merged player, among others.

As shown in FIG. 4, the controller device 104 also includes a user interface 440 that is generally configured to facilitate user access and control of the MPS 100. The user interface 440 may include a touch-screen display or other physical interface configured to provide various graphical controller interfaces, such as the controller interfaces 540a and 540b shown in FIGS. 5A and 5B. Referring to FIGS. 5A and 5B together, the controller interfaces 540a and 540b includes a playback control region 542, a playback zone region 543, a playback status region 544, a playback queue region 546, and a sources region 548. The user interface as shown is just one example of an interface that may be provided on a network device, such as the controller device shown in FIG. 4, and accessed by users to control a media playback system, such as the MPS 100. Other user interfaces of varying formats, styles, and interactive sequences may alternatively be implemented on one or more network devices to provide comparable control access to a media playback system.

The playback control region 542 (FIG. 5A) may include selectable icons (e.g., by way of touch or by using a cursor) that, when selected, cause playback devices in a selected playback zone or zone group to play or pause, fast forward, rewind, skip to next, skip to previous, enter/exit shuffle mode, enter/exit repeat mode, enter/exit cross fade mode, etc. The playback control region 542 may also include selectable icons that, when selected, modify equalization settings and/or playback volume, among other possibilities.

The playback zone region 543 (FIG. 5B) may include representations of playback zones within the MPS 100. The playback zones regions 543 may also include a representation of zone groups, such as the Dining Room+Kitchen zone group, as shown.

In some embodiments, the graphical representations of playback zones may be selectable to bring up additional selectable icons to manage or configure the playback zones in the MPS 100, such as a creation of bonded zones, creation of zone groups, separation of zone groups, and renaming of zone groups, among other possibilities.

For example, as shown, a “group” icon may be provided within each of the graphical representations of playback zones. The “group” icon provided within a graphical representation of a particular zone may be selectable to bring up options to select one or more other zones in the MPS 100 to be grouped with the particular zone. Once grouped, playback devices in the zones that have been grouped with the particular zone will be configured to play audio content in synchrony with the playback device(s) in the particular zone. Analogously, a “group” icon may be provided within a graphical representation of a zone group. In this case, the “group” icon may be selectable to bring up options to deselect one or more zones in the zone group to be removed from the zone group. Other interactions and implementations for grouping and ungrouping zones via a user interface are also possible. The representations of playback zones in the playback zone region 543 (FIG. 5B) may be dynamically updated as playback zone or zone group configurations are modified.

The playback status region 544 (FIG. 5A) may include graphical representations of audio content that is presently being played, previously played, or scheduled to play next in the selected playback zone or zone group. The selected playback zone or zone group may be visually distinguished on a controller interface, such as within the playback zone region 543 and/or the playback status region 544. The graphical representations may include track title, artist name, album name, album year, track length, and/or other relevant information that may be useful for the user to know when controlling the MPS 100 via a controller interface.

The playback queue region 546 may include graphical representations of audio content in a playback queue associated with the selected playback zone or zone group. In some embodiments, each playback zone or zone group may be associated with a playback queue comprising information corresponding to zero or more audio items for playback by the playback zone or zone group. For instance, each audio item in the playback queue may comprise a uniform resource identifier (URI), a uniform resource locator (URL), or some other identifier that may be used by a playback device in the playback zone or zone group to find and/or retrieve the audio item from a local audio content source or a networked audio content source, which may then be played back by the playback device.

In one example, a playlist may be added to a playback queue, in which case information corresponding to each audio item in the playlist may be added to the playback queue. In another example, audio items in a playback queue may be saved as a playlist. In a further example, a playback queue may be empty, or populated but “not in use” when the playback zone or zone group is playing continuously streamed audio content, such as Internet radio that may continue to play until otherwise stopped, rather than discrete audio items that have playback durations. In an alternative embodiment, a playback queue can include Internet radio and/or other streaming audio content items and be “in use” when the playback zone or zone group is playing those items. Other examples are also possible.

When playback zones or zone groups are “grouped” or “ungrouped,” playback queues associated with the affected playback zones or zone groups may be cleared or re-associated. For example, if a first playback zone including a first playback queue is grouped with a second playback zone including a second playback queue, the established zone group may have an associated playback queue that is initially empty, that contains audio items from the first playback queue (such as if the second playback zone was added to the first playback zone), that contains audio items from the second playback queue (such as if the first playback zone was added to the second playback zone), or a combination of audio items from both the first and second playback queues. Subsequently, if the established zone group is ungrouped, the resulting first playback zone may be re-associated with the previous first playback queue or may be associated with a new playback queue that is empty or contains audio items from the playback queue associated with the established zone group before the established zone group was ungrouped. Similarly, the resulting second playback zone may be re-associated with the previous second playback queue or may be associated with a new playback queue that is empty or contains audio items from the playback queue associated with the established zone group before the established zone group was ungrouped. Other examples are also possible.

With reference still to FIGS. 5A and 5B, the graphical representations of audio content in the playback queue region 646 (FIG. 5A) may include track titles, artist names, track lengths, and/or other relevant information associated with the audio content in the playback queue. In one example, graphical representations of audio content may be selectable to bring up additional selectable icons to manage and/or manipulate the playback queue and/or audio content represented in the playback queue. For instance, a represented audio content may be removed from the playback queue, moved to a different position within the playback queue, or selected to be played immediately, or after any currently playing audio content, among other possibilities. A playback queue associated with a playback zone or zone group may be stored in a memory on one or more playback devices in the playback zone or zone group, on a playback device that is not in the playback zone or zone group, and/or some other designated device. Playback of such a playback queue may involve one or more playback devices playing back media items of the queue, perhaps in sequential or random order.

The sources region 548 may include graphical representations of selectable audio content sources and/or selectable voice assistants associated with a corresponding VAS. The VASes may be selectively assigned. In some examples, multiple VASes, such as AMAZON's Alexa, MICROSOFT's Cortana, etc., may be invokable by the same NMD. In some embodiments, a user may assign a VAS exclusively to one or more NMDs. For example, a user may assign a first VAS to one or both of the NMDs 102a and 102b in the Living Room shown in FIG. 1A, and a second VAS to the NMD 103f in the Kitchen. Other examples are possible.

d. Example Audio Content Sources

The audio sources in the sources region 548 may be audio content sources from which audio content may be retrieved and played by the selected playback zone or zone group. One or more playback devices in a zone or zone group may be configured to retrieve for playback audio content (e.g., according to a corresponding URI or URL for the audio content) from a variety of available audio content sources. In one example, audio content may be retrieved by a playback device directly from a corresponding audio content source (e.g., via a line-in connection). In another example, audio content may be provided to a playback device over a network via one or more other playback devices or network devices. As described in greater detail below, in some embodiments audio content may be provided by one or more media content services.

Example audio content sources may include a memory of one or more playback devices in a media playback system such as the MPS 100 of FIG. 1, local music libraries on one or more network devices (e.g., a controller device, a network-enabled personal computer, or a networked-attached storage (“NAS”)), streaming audio services providing audio content via the Internet (e.g., cloud-based music services), or audio sources connected to the media playback system via a line-in input connection on a playback device or network device, among other possibilities.

In some embodiments, audio content sources may be added or removed from a media playback system such as the MPS 100 of FIG. 1A. In one example, an indexing of audio items may be performed whenever one or more audio content sources are added, removed, or updated. Indexing of audio items may involve scanning for identifiable audio items in all folders/directories shared over a network accessible by playback devices in the media playback system and generating or updating an audio content database comprising metadata (e.g., title, artist, album, track length, among others) and other associated information, such as a URI or URL for each identifiable audio item found. Other examples for managing and maintaining audio content sources may also be possible.

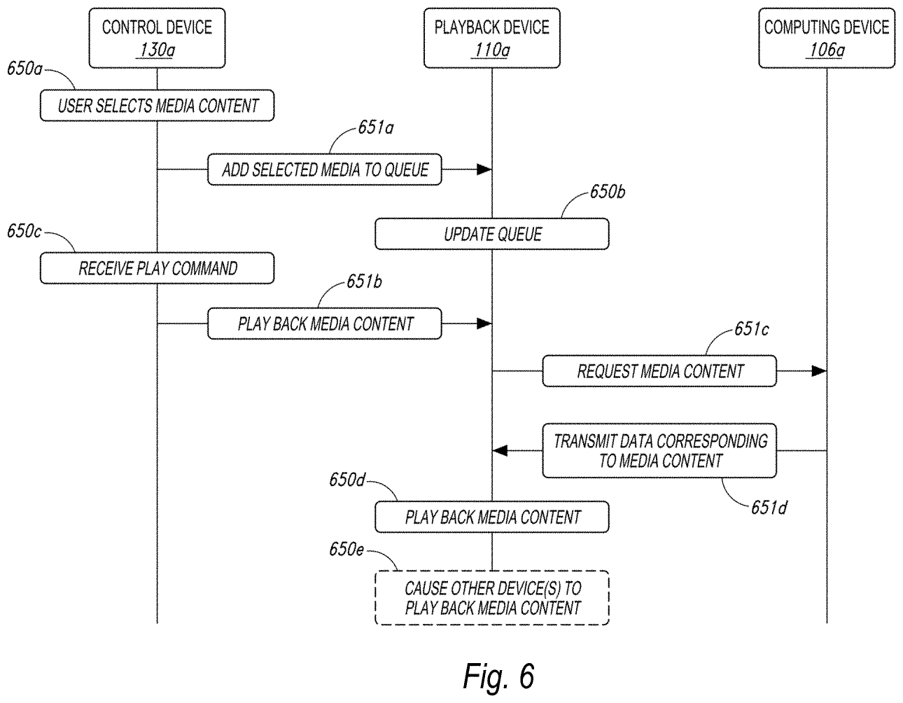

FIG. 6 is a message flow diagram illustrating data exchanges between devices of the MPS 100. At step 650a, the MPS 100 receives an indication of selected media content (e.g., one or more songs, albums, playlists, podcasts, videos, stations) via the control device 104. The selected media content can comprise, for example, media items stored locally on or more devices (e.g., the audio source 105 of FIG. 1C) connected to the media playback system and/or media items stored on one or more media service servers (one or more of the remote computing devices 106 of FIG. 1B). In response to receiving the indication of the selected media content, the control device 104 transmits a message 651a to the playback device 102 (FIGS. 1A-1C) to add the selected media content to a playback queue on the playback device 102.

At step 650b, the playback device 102 receives the message 651a and adds the selected media content to the playback queue for play back.

At step 650c, the control device 104 receives input corresponding to a command to play back the selected media content. In response to receiving the input corresponding to the command to play back the selected media content, the control device 104 transmits a message 651b to the playback device 102 causing the playback device 102 to play back the selected media content. In response to receiving the message 651b, the playback device 102 transmits a message 651c to the computing device 106 requesting the selected media content. The computing device 106, in response to receiving the message 651c, transmits a message 651d comprising data (e.g., audio data, video data, a URL, a URI) corresponding to the requested media content.

At step 650d, the playback device 102 receives the message 651d with the data corresponding to the requested media content and plays back the associated media content.

At step 650e, the playback device 102 optionally causes one or more other devices to play back the selected media content. In one example, the playback device 102 is one of a bonded zone of two or more players (FIG. 1M). The playback device 102 can receive the selected media content and transmit all or a portion of the media content to other devices in the bonded zone. In another example, the playback device 102 is a coordinator of a group and is configured to transmit and receive timing information from one or more other devices in the group. The other one or more devices in the group can receive the selected media content from the computing device 106, and begin playback of the selected media content in response to a message from the playback device 102 such that all of the devices in the group play back the selected media content in synchrony.

### III. Example Room Sound Modes

Example techniques described herein relate to one or more playback devices 102 that are operable in a plurality of room sound modes. In a given room sound mode, certain setting and/or configurations are applied to further use cases associated with that mode.

a. Example Room Sound Modes

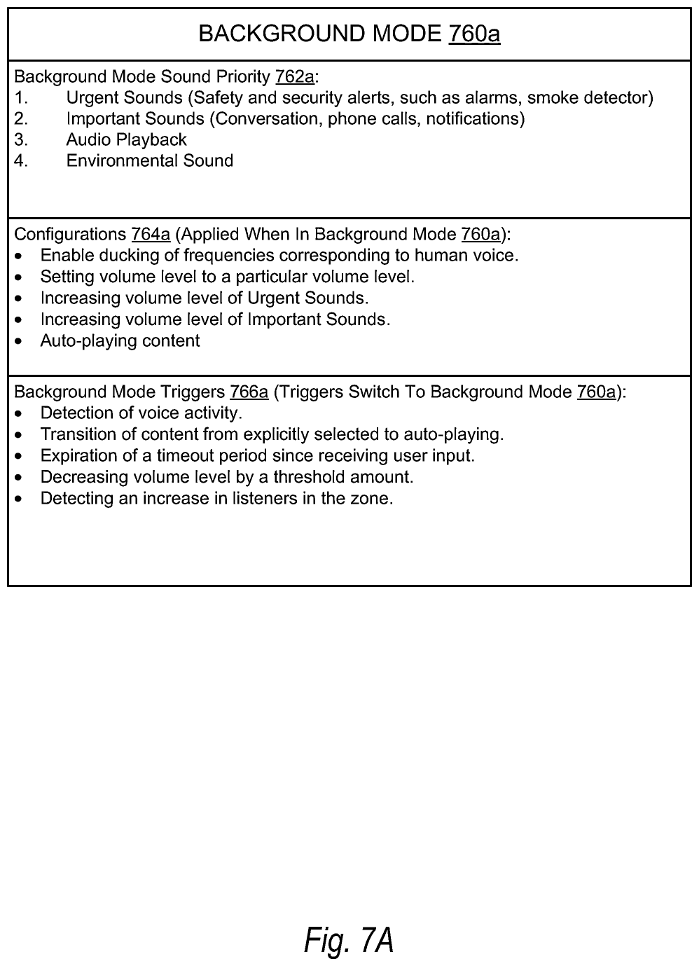

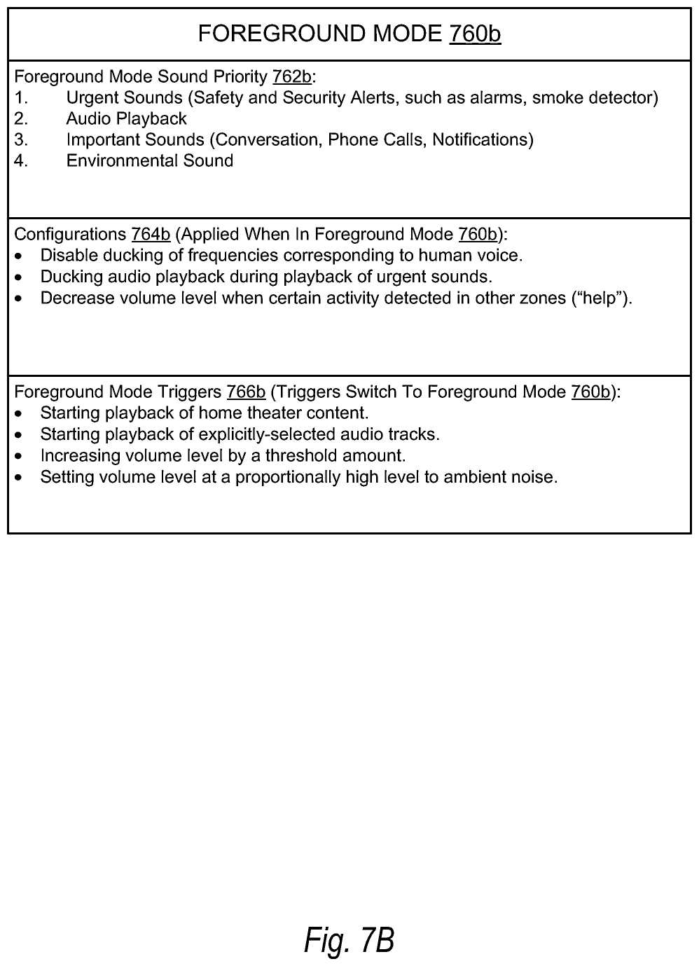

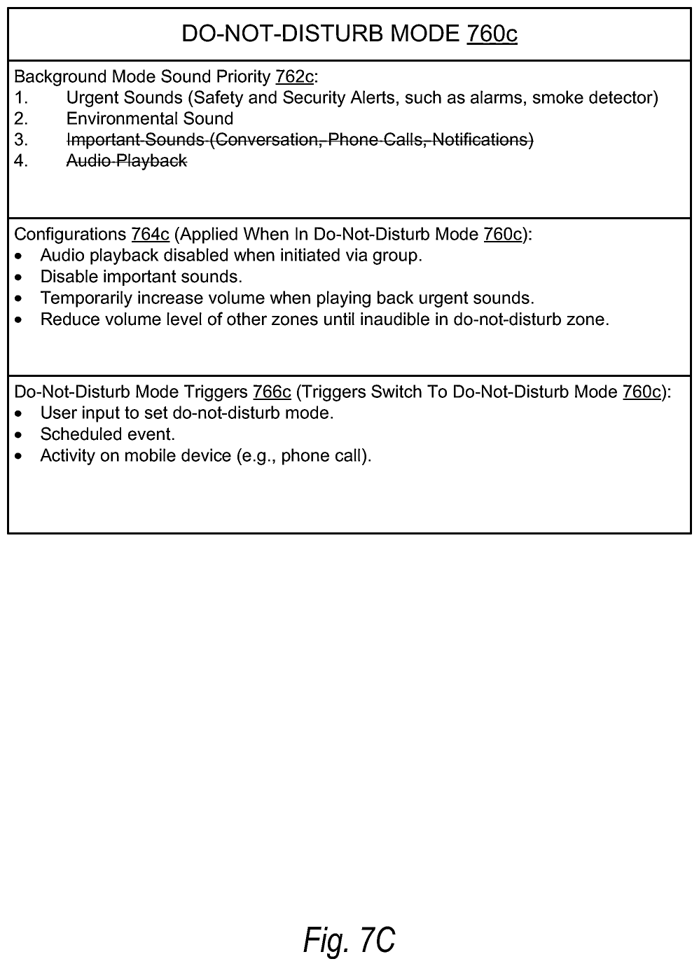

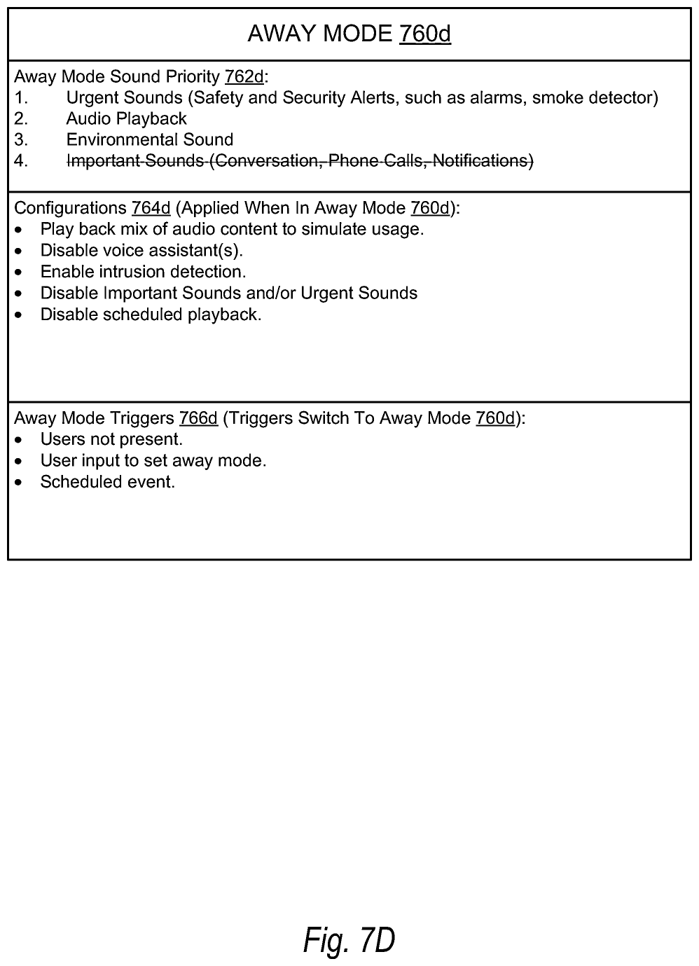

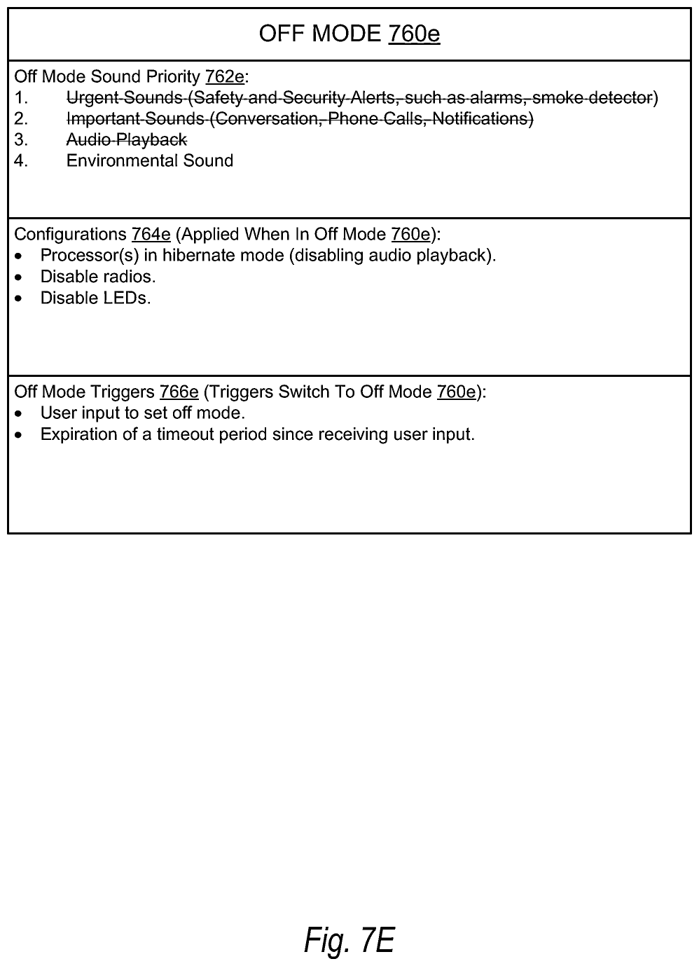

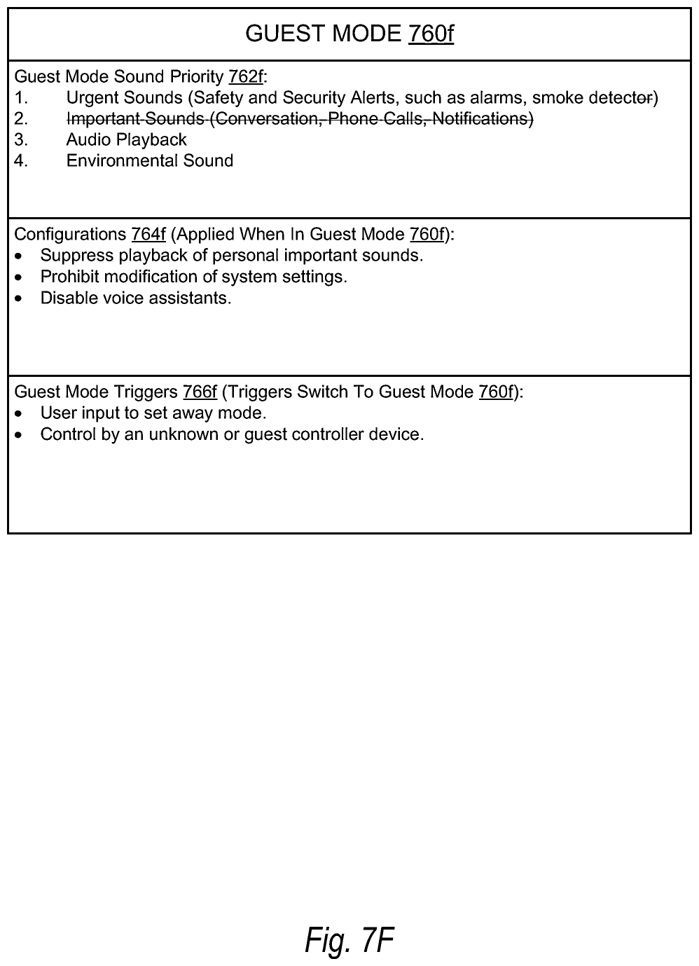

FIGS. 7A, 7B, 7C, 7D, 7E, and 7F are diagrams illustrating respective room sound modes 760, which are representative of a plurality of sound modes that may be implemented by the media playback system 100 (FIGS. 1A and 1B). Individual playback devices 102 in the media playback system 100 may be operable in the room sound modes 760.

In one aspect, the plurality of sound modes 760 implement respective sound priorities 762. Each sound mode 760 may prioritize different types of sounds according to the use case associated with its mode. Generally, each sound mode 760 prioritizes sound differently than other sound modes, but, in some cases, two or more sound modes 760 may prioritize sound types similarly.

For the purpose of illustration, the sound priorities 762 define four different categories or types of sound. These categories include urgent sounds (e.g., safety and security alerts), important sounds (e.g., conversation, phone calls, and notifications), audio playback (by the playback devices 102), and environmental sound.

Urgent sounds, such as safety and security alerts, may be generated from various smart devices integrated within the media playback system 100, such as smart smoke detectors (e.g., to generate smoke and/or carbon monoxide alarms) or home security systems (to generate intrusion alerts), among other examples. In operation, when such a device generates an alert, data representing the alert may be propagated to the playback device(s) 102 via the LAN 111 and/or the networks 107 (FIG. 1B). Based on receiving such data, the playback device(s) 102 may play back a sound corresponding to the generated alert and/or take other action (e.g., pushing a notification to one or more mobile devices registered with the media playback system). Within examples, these sounds may be played on multiple playback devices 102 throughout the household to facilitate notifying a user or users throughout the household of the alert.

In some examples, the playback device(s) 102 of the media playback system may be configured to generate alerts from integrated sensors. For instance, in certain situations the playback device(s) 102 may configure the microphones 222 to detect certain sounds, such as glass breaking, and generate alerts Similar to the alerts from other smart devices, when such a playback device 102 generates an alert, data representing the alert may be propagated to the playback device(s) 102 via the LAN 111 and/or the networks 107 (FIG. 1B). Based on receiving such data, the playback device(s) 102 may play back a sound corresponding to the generated alert and/or take other action (e.g., pushing a notification to one or more mobile devices registered with the media playback system).

Important sounds include conversation (e.g.,) and notifications. Conversation sounds may include conversations between two users in the household, or by a user on the phone with another person, among other examples that involve human voice activity in the environment. With respect to notifications, the playback devices 102 may integrate with various cloud services, such as voice assistant services (e.g., VAS 190), IOT cloud services (e.g., to support various smart devices), cloud email and calendar services, as well as other cloud services. Such services may generate notifications based on various events. Data representing such events may be propagated to the media playback system 100 via the networks 107 and/or the LAN 111 (FIG. 1B). When the media playback system 100 receives such data, the playback device(s) 102 may play back notification audio corresponding to the events.

Environmental audio includes ambient or background noise (or lack thereof) in the environment. Examples include water running, traffic noise from outside, appliances, such as HVAC and dishwashers. In the context of room sound modes, a user might want to prioritize environmental audio when desiring quiet in their personal space (e.g., while sleeping or studying) so as to avoid interruptions from audio playback.

In another aspect, the plurality of sound modes 760 implement respective configurations 764. In a sense, the set of configurations applied during a given sound mode define that mode. Generally, the set of configurations for a given sound mode are designed to facilitate a use case (or use cases) associated with that mode. For instance, during an away mode, the playback device(s) 102 may apply a set of configurations corresponding to the user(s) being away from the household. As another example, during a do-not-disturb mode, the playback device(s) 102 may apply a set of configurations that promote the user(s) not being disturbed. As discussed in further detail below, other modes may have their own respective sets of configurations for their respective use case(s).

By applying the configurations 764 for a given mode, the media playback system 100 changes how the playback device(s) 102 function. In some examples, the playback device(s) 102 may apply one or more configurations 764 by modifying state information. As described above in connection with section II, the playback device(s) 102 may maintain state information representing a current state of the playback device(s) 102. In addition to representing the current state, such state information may govern how the playback device(s) 102 functions. For instance, by changing a state for a given function from enabled to disabled, the playback device(s) 102 may disable that function on the playback device(s) 102.

Further, the modes 760 themselves may be implemented as states on the playback device(s) 102. Then, by switching modes, the playback device(s) 102 may apply all of the configurations 764 corresponding to that mode in one operation (i.e., changing a mode state variable from one mode to another mode). Alternatively, the modes may be implemented as respective functions. By calling a function for a particular mode (e.g., enterForegroundMode), the function applies the corresponding configuration to that mode, thereby changing the functioning of the playback devices 102 relative to the previous mode.

In a third aspect, the plurality of sound modes 760 implement respective triggers 766. Generally, each mode may have one or more trigger conditions that will trigger transitioning to that mode when they are detected to occur. Alternatively, the mode may be set explicitly using user input to a GUI (e.g., on a control device 104) or VUI (e.g., via a NMD 103). In some cases, manually setting a mode is considered occurrence of a trigger condition for that mode.

FIG. 7A illustrates an example background mode 760a. The playback device(s) 102 are intended to be operable in the background mode 760a when audio playback from the playback device(s) 102 is not the focus within the listening environment. Instead, as illustrated by the background mode sound priority 762a, important sounds, such as conversation, phone calls, and notifications, are prioritized above audio playback. However, urgent sounds, such as safety and security alerts, such as alarms, are prioritized above the important sounds. One or more users in a household may utilize the background mode 760a in the kitchen 101h, the dining room 101g, and the living room 101f when having a social gathering (e.g., involving conversation).

To implement the background mode 760a, the playback device(s) 102 apply a set of configurations 764a. The set of configurations 764a are representative, and should not be considered limiting. Exemplary background modes may include additional or fewer configurations. Yet, at the same time, exemplary configurations should further the use case of “background” audio playback during the background mode 760a.

In exemplary embodiments, the configurations 764a include enabling ducking of frequencies corresponding to human voice. In particular, while in the background mode 760a, the playback device(s) 102 may duck frequencies corresponding to human voice when voice activity is detected by the playback device(s) 102 (e.g., using a voice activity detector). Ducking involves temporarily reducing the volume of audio content in certain frequency bands, examples of which are disclosed in U.S. patent application Ser. No. 15/438,749, which is hereby incorporated by reference herein in its entirety Such ducking may make conversation (i.e., human voice) easier to comprehend in the environment.

The configurations 764a may also include setting volume level to a particular volume level (e.g., a relatively low volume level). In some cases, the playback device(s) 102 may set volume level to the particular volume level when in the background mode 760a only when the volume level exceeds a certain threshold level (e.g., above 50% volume), which may interfere with important sounds in the environment. As another example, the configurations 764a may include setting a volume limit.

Within examples, the threshold level may be dynamic based on a level of ambient audio in the environment. For instance, when the ambient noise level is relatively high (e.g., because of a lot of people talking), the playback device(s) 102 may set the threshold level relatively higher than in a quiet room. Conversely, when the ambient noise level is relatively low, the playback device(s) 102 may set the threshold level relatively lower. The playback device(s) 102 may detect ambient noise level using the microphones 222.

In further examples, the configurations 764a may include increasing a volume level of the playback device when playing back urgent sounds, such as alerts, and/or important sounds, such as notifications. Since the volume level is generally relatively low during the background mode 760a, alerts or notifications played at this volume level might not grab the attention of the user(s). To promote such alerts and notifications being noticed, the playback device(s) 102 may temporality increase volume level (e.g., to a particular pre-defined level, or to a level that is at least a threshold above ambient noise level) when playing back urgent sounds and/or important sounds. To further promote such alerts and notifications, the playback device(s) 102 may concurrently or simultaneously pause playback of audio with playback of the alerts or notifications. Further example techniques to mix audio streams together for playback are described in U.S. Pat. No. 9,664,341 filed Feb. 9, 2015, and titled “Synchronized Audio Mixing,” which is herein incorporated by reference in its entirety.

Yet further, the configurations 764a may include auto-playing content. For instance, after a playback queue associated with the playback device(s) 102 is exhausted (e.g., the end of the queue is reached, or each audio track in the queue has been played back or skipped through in a shuffle mode), the playback device(s) 102 may add additional audio tracks to the payback queue, so as to continue playback. In some examples, the playback device(s) 102 might not auto-play additional content, perhaps when the source of the audio tracks in the playback queue already provides an auto-play mechanism. For instance, some streaming audio services provide an auto-play mechanism when playback reaches the end of a container, such as a playlist or album.

The playback device(s) 102 may select the additional audio tracks based on various considerations. For instance, the playback device(s) 102 may select additional audio tracks that are similar to audio tracks that were in the playback queue. Alternatively, the playback device(s) 102 may select audio tracks according to a genre or mood. In further examples, the playback device(s) 102 may seed an Internet radio station with metadata from audio tracks in the playback queue. U.S. Pat. No. 10,747,409 titled “Continuous Playback Queue,” which is hereby incorporated by reference in its entirety, provides in more detail some examples for auto-playing content.

The playback device(s) 102 may be configured to switch from operating in one of the other modes 760 to operating in the background mode 760a when occurrence of one of the background mode trigger conditions 766a is detected. The background mode triggers 766a are representative of trigger conditions that may be suitable for the exemplary background mode 760a, and should not be considered limiting. Exemplary background modes may include additional or fewer trigger conditions. Yet, at the same time, exemplary trigger conditions should be reflective of conditions that are suitable for entering the background mode 760a and its attendant configurations 764a.

The background mode trigger conditions 766a may include detection of voice activity. The presence of voice activity in audible range of the playback device(s) 102 may indicate that the user(s) are engaged in conversation. Based on the assumption that users engaged in conversation generally want to be able to hear one another over audio playback, the playback device(s) 102 may be configured to trigger the background mode (and its attendant configurations 764a, such as ducking of frequencies corresponding to human voice) when voice activity is detected. As described above in section II, the playback device(s) 102 may include a voice activity detector (VAD), which may be implemented as part of an NMD in some instances. The playback device(s) may utilize the VAD to detect whether voice activity (i.e., conversation) is present in the environment.

In further examples, the background mode trigger conditions 766a may include transitioning of content from explicitly-selected content to auto-playing content. For instance, a user may explicitly select an album for playback. At the start of playback, the user may be more attentively listening to the album. However, over time, the user may become engaged in other activities. After the album concludes, playback may continue via a native or third-party (e.g., streaming audio service) auto-play mechanism. Occurrence of this transition from explicitly-selected content to auto-playing content may be configured as a trigger for the background mode 760a. In other words, the user(s) allowing this automatic transition (and not explicitly selecting other content) may be assumed to indicate that the user is now engaged in background listening and the background mode 760a mode is appropriate (e.g., over a foreground mode).

In some instances, the background mode trigger conditions 766a include expiration of a timeout period since receiving user input. As discussed above, a user may control the playback device(s) 102 using a GUI (e.g., on a control device 104), a VUI (e.g., via an NMD 103), or via controls on the playback device(s) 102 themselves (e.g., the control area 232 (FIG. 2B)). If no input is received via any of these control mechanisms during a timeout period, the timeout period may expire. By not interacting with the media playback system during this timeout period, the user may be assumed to be interacting with the playback device(s) 102 in a background manner. As such, the playback device(s) 102 may be configured to transition into the background mode 760a when the expiration of the timeout period occurs.

Another example background mode trigger condition 766a is decreasing volume level (e.g., by a threshold amount, or below a threshold level). When volume is decreased to a level that is relatively low with respect to ambient noise, the user may be assumed to be listening to the audio playback as background. As such, the playback device(s) 102 may be configured to transition into the background mode 760a when volume level is decreased.

Another example background mode trigger condition 766a is detecting an increase in a number of listeners in the zone. Such a change may be indicative of a social gathering (e.g., a party) where audio playback is generally background to the other activities (e.g., socializing) occurring at the party. Any suitable presence detection technique may be utilized to detect listeners. Several example techniques for listener detection are disclosed in U.S. Pat. No. 9,084,058 titled “Sound Field Calibration Using Listener Location,” which is hereby incorporated by reference in its entirety. Other example techniques are described in U.S. Application No. 63/072,888 filed Aug. 31, 2020, and titled “Ultrasonic Transmission for Presence Detection,” which is herein incorporated by reference in its entirety.

FIG. 7B illustrates an example foreground mode 760b. In contrast to the background mode 760a, in the foreground mode 760b, the playback device(s) 102 are intended to be operable in the foreground mode 760b when audio playback from the playback device(s) 102 is the focus within the listening environment. As shown by the foreground mode sound priority 762b, audio playback is prioritized above important sounds, such as conversation, phone calls, and notifications. However, like the background mode 760b, urgent sounds, such as safety and security alerts, such as alarms, are prioritized above the important sounds. One or more users in a household may utilize the foreground mode 760b when actively listening to audio content (e.g., when enjoying a new album using the bookshelf 102d or during home theatre playback in the den 101d (FIGS. 3C and 3D)).

To implement the foreground mode 760b, the playback device(s) 102 apply a set of configurations 764b. The set of configurations 764b are representative, and should not be considered limiting. Exemplary foreground modes may include additional or fewer configurations. Yet, at the same time, exemplary configurations should further the use case of “foreground” audio playback during the foreground mode 760b.

In exemplary embodiments, the configurations 764b include disabling ducking of frequencies corresponding to human voice. As noted above, in contrast to the background mode 760a, the priority of the foreground mode 760b is the audio playback. Altering the content by ducking may interfere with the user's enjoyment of the audio playback, so such alternations are disabled, foregone, or otherwise prevented by the configurations 764b applied during the foreground mode 760b.

At the same time, however, the configurations 764b include ducking of the audio playback during concurrent playback of urgent sounds. That is, since the foreground mode sound priority 762b prioritizes urgent sounds over the audio playback, the playback device(s) 102 may temporarily reduce (or even mute) the volume level of the audio playback (e.g., music) when urgent sounds, such as safety and security alerts, are played back concurrently with the audio playback.

While generally avoiding adjustments that may interfere with a user's enjoyment of audio playback in the foreground mode 760b, the playback device(s) 102 may apply other filtering, such as equalizations intended to enhance the user's enjoyment of the audio playback when in the foreground mode 760b. Such adjustments include calibration equalizations (e.g., to offset acoustic characteristics and/or spatial characteristics of the listening environment) and user-defined equalizations. Notably, such adjustments may be applied during other modes as well, such as the background mode 760a, as they may be considered independent of the room sound modes 760.

On the other hand, in some implementations, the configurations 764 for a given mode 760 may include application of a particular equalization. For instance, the configuration 764a of the background mode 760a may include applying a “neutral” equalization instead of the user-defined equalization. User-defined equalizations may have characteristics (e.g., boosts to bass frequencies) that interfere with the important sounds prioritized during the background mode 760a.

The configurations 764b applied by the playback device(s) 102 in the foreground mode 760b may also include decreasing volume level when certain activity is detected in other zones. This may include detection of certain words. As noted above, example playback devices 102 may implement NMDs 103, which may include integrated voice assistants. Such voice assistants may detect certain words indicative of issues (e.g., a user input of “help”) on any playback device 102 in the media playback system 100 (which implements an NMD 103) and responsively cause the playback device(s) 102 in the foreground mode to temporarily reduce their volume (to promote this issue being heard). In further examples, the playback device(s) 102 in the foreground mode may additionally or alternatively play back an alert associated with detection of one of these issues.

The playback device(s) 102 may be configured to switch from operating in one of the other modes 760 to operating in the foreground mode 760b when occurrence of one of the foreground mode trigger conditions 766b is detected. The foreground mode triggers 766b are representative of trigger conditions that may be suitable for the exemplary foreground mode 760a, and should not be considered limiting. Exemplary foreground modes may include additional or fewer trigger conditions. Yet, at the same time, exemplary trigger conditions should be reflective of conditions that are suitable for entering the foreground mode 760b and its attendant configurations 764b.

The foreground mode trigger conditions 766b may include starting playback of certain content. For instance, starting playback of home theatre content (e.g., audio tracks of television or movie) may be configured as a trigger condition 766a, as users are generally active listeners to such content. As another example, starting playback of explicitly-selected audio tracks may be configured as a trigger condition 766a, as a user performing the action of selecting particular audio tracks may be assumed to represent an intent to attentively listen to the particular audio tracks. Conversely, as noted above, starting playback of a implicitly-selected content, such as mood-based playlist or an Internet radio station, may signal an intent to utilize the audio playback as background (such that the background mode 760a may be triggered).

As further examples, the foreground mode trigger conditions 766b may include certain volume settings. For example, increasing volume level (e.g., by a threshold amount, or above a threshold level). When volume is increased to a level that is relatively high with respect to ambient noise, the user may be assumed to be attentively listening to the audio playback (as the relatively loud playback may interfere with other activities). As such, the playback device(s) 102 may be configured to transition into the foreground mode 760b when volume level is increased.

FIG. 7C illustrates an example do-not-disturb mode 760c. In contrast to the background mode 760a and the foreground mode 760b, in the do-not-disturb mode 760c, the playback device(s) 102 are intended to be operable in the away mode 760c when ambient noise is the focus within the listening environment. In other words, the user does not wish to be disturbed by audio playback and desires instead to prioritize quiet (or any ambient noise in the environment).

As shown by the do-not-disturb mode sound priority 762c, ambient noise is prioritized above important sounds, such as conversation, phone calls, and notifications, as well as audio playback. Further, important sounds and/or audio playback may be disabled or otherwise restricted, as represented by the strikethrough of these categories of sound. However, like the background mode 760b, urgent sounds, such as safety and security alerts, such as alarms, are prioritized above the important sounds. One or more users in a household may utilize the do-not-disturb mode 760b when on a work conference call in the office 101e, when sleeping in the bedroom 101b (especially if on a different sleep schedule than other household members, such as night shift workers), or in any other use case where the user does not want to be disturbed by audio playback.

To implement the do-not-disturb mode 760c, the playback device(s) 102 apply a set of configurations 764c. The set of configurations 764c are representative, and should not be considered limiting. Exemplary do-not-disturb modes may include additional or fewer configurations. Yet, at the same time, exemplary configurations should further the use case of a user desiring not to be disturbed by audio playback during the do-not-disturb mode 760c.

The configurations 764c may include disabling or restricting certain audio playback. For instance, the playback device(s) 102 may apply a configuration that disables audio playback when initiated via a group (FIG. 3A). To illustrate, a user in the living room may start playback on the living room 101h, not realizing that the living room 101h is still in a zone group with the office 101h, and thereby interrupt another user working in the office 101h. However, if the office 101h was in a do-not-disturb mode, such playback would be restricted on the playback device 102n in the office 101h by the media playback system 100.

As another example, when in the do-not-disturb mode 760c, the playback device(s) 102 may disable important sounds, such as notifications. This setting may prevent playback of such sounds from interrupting or otherwise disturbing users in proximity to the playback device(s) 102. Such notifications may be cached, e.g., in a first-in-first-out buffer, and played back when the playback device(s) 102 switch to another mode, such as the background mode 760a or the foreground mode 760b.

At the same time, however, the configurations 764c may include playback of urgent sounds. Further, the playback device(s) 102 may temporarily increase a volume level of the playback device(s) 102 when playing back urgent sounds (perhaps when the volume level is set relatively low relative to ambient noise). Such configurations may promote the urgent sounds being noticed by the user(s).

In addition, the configurations 764c may include reducing the volume level of other playback device(s) 102 until inaudible by the playback device(s) 102 in the do-not-disturb mode. For instance, audio playback in the bedroom zone 101c may spill over to the bedroom 101b, as these zones share a wall (FIG. 1A). When the bedroom 101b is in the do-not-disturb mode, the playback devices 102g and/or 101f in the bedroom 101b may detect such playback (and its apparent sound pressure level) via their respective microphones 222. If the sound pressure level exceeds a certain threshold level (e.g., that of a quiet room, or approximately 30 dB), the media playback system 100 may cause the playback device 102e to (gradually) decrease its volume setting until the detected sound from the playback device 102e is below the threshold sound pressure level.

Yet further, in some examples, the configurations 764c may include play back masking noise. Masking noise, such as pink noise or white noise, may be played back in one zone to reduce or prevent bleed-over from playback in other zones, which may render such playback in other zones less disruptive. At the same time, such playback of masking noise is played back at a (low) level to avoid disruption in the zone operating in the do-not-disturb mode 760c.

The playback device(s) 102 may be configured to switch from operating in one of the other modes 760 to operating in the do-not-disturb mode 760c when occurrence of one of the do-not-disturb mode trigger conditions 766c is detected. The do-not-disturb mode triggers 766c are representative of trigger conditions that may be suitable for the exemplary do-not-disturb mode 760c, and should not be considered limiting. Exemplary do-not-disturb modes may include additional or fewer trigger conditions. Yet, at the same time, exemplary trigger conditions should be reflective of conditions that are suitable for entering the do-not-disturb mode 760c and its attendant configurations 764c.

The do-not-disturb mode trigger conditions 766c may include user input to set or schedule the do-not-disturb mode 760c. For instance, a user may set the do-not-disturb mode 760c using a VUI by speaking a voice input such as “Set do-not-disturb in office” or “Schedule do-not-disturb upstairs for 10 pm tonight” Alternatively, a user may use a GUI on a control device 104 to set or schedule a do-not-disturb mode. For instance, a user may schedule a repeating do-not-disturb mode in the office 101e during a weekly Monday conference call using a GUI on the control device 104b or may set a do-not-disturb mode in the bedroom 101c right before a nap.

In further examples, the do-not-disturb mode trigger conditions 766c include a scheduled event in a user's calendar(s). The media playback system 100 may integrate with one or more cloud services (FIG. 1B), such as an email and calendar cloud service. The user may opt to share data between the media playback system 100 and such a cloud service. The cloud service may share the calendar (e.g., in advance of the event) or event data (e.g., at the time of the event) via the networks 107 and/or the LAN 111. In such a case, the media playback system 100 may be configured to enter the do-not-disturb mode 760c during certain appointments (e.g., appointments that are located at the location of the media playback system 100). Other appointments, such as appointments at other locations, may trigger a different mode, such as the away mode 760d.

Notably, while not explicitly shown as example trigger conditions for each mode, in certain implementations, the user may set any mode using user input in the same or similar manner as the do-not-disturb mode 760c. However, due to the nature of the do-not-disturb mode 760c, the user may be likely to use user input to set or schedule the do-not-disturb mode 760c as compared with certain other modes (which may be triggered based on usage conditions).

FIG. 7D illustrates an example away mode 760d. In contrast to the modes 760a-c, the away mode 760d is intended to be utilized when the user(s) are away from the media playback system 100. Since the users are not expected to be home when the playback device(s) 102 are operating in the away mode 760d, sound priorities are less of a concern. Instead, the configurations 764d are applied in a manner intended to promote security and user privacy.

To implement the away mode 760d, the playback device(s) 102 apply a set of configurations 764d. The set of configurations 764d are representative, and should not be considered limiting. Exemplary away modes may include additional or fewer configurations. Yet, at the same time, exemplary configurations should further the use case of users being away from their home or office (or wherever their media playback system is located).

The configurations 764d may include playing back a mix of audio content to simulate presence of users in the household. For instance, various zones in the media playback system 100 (FIG. 1A) may play back different content at various times throughout the day and evening to simulate realistic usage. For instance, playback device(s) 102 in the away mode 760d may switch between various content and further may perhaps change volume levels, skip forward in playback queues, and take other actions without user input to simulate usage. An uninvited guest may be led to believe that the users are home by such simulated usage. In further examples, to simulate presence, the playback device(s) 102 in the away mode 760d may play back human voices (e.g., simulated conversion or simulated interactions with a voice assistant). In connection with such simulated presence, the media playback system 100 may disable other scheduled playback, such as morning wake-up alarms or zone scenes, among other examples.

In some cases, in an effort to reduce costs to the users and/or one or more streaming audio services, the media playback system 100 may select particular media items to include in the mix of audio content. For instance, in an effort to reduce royalty rates, the media playback system 100 may select particular media items to include in the mix of audio content based on relatively lower royalty rates including royalty-free audio content for the particular media items relative to other media items in a library of the media playback system. In an example, certain streaming audio services may mark or otherwise designate lower royalty media (e.g., via metadata), which the media playback system 100 may use to select the audio tracks. In another example, particular playlists or radio stations may be designated by the streaming audio service as royalty-free or low royalty rate playlists. For these playlists or radio stations, the audio content of the playlist or radio may be comprised solely of royalty-free music and/or music below a given royalty rate threshold.

Additionally or alternatively, to reduce network costs (e.g., an ISP bandwidth cap) or costs associated with hosting content at a content delivery network (CDN), the media playback system 100 may select local media items (i.e., media items hosted on the LAN 111) or media items with lower bitrates. For instance, the playback device(s) 102 may, by default, be configured to stream audio tracks from a given streaming audio service at a high quality (e.g., 320 kbps). However, in the away mode 760d, the playback device(s) 102 may instead be configured to stream audio tracks from the streaming audio service at a relatively lower quality (e.g., 96 kbps), which reduces the amount of data transferred during playback.

In additional examples, the configurations 764d may include one or more configurations to protect user privacy. For instance, the configurations 764d may include disabling voice assistant(s), which may prevent uninvited guests from accessing or using personal user information (e.g., to order items using a voice assistant) or to read a calendar.

As another example, the configurations 764d may include disabling playback of important sounds. Such a configuration may prevent playback of notifications from revealing personal information if uninvited guests are present. On the other hand, the configurations 764d may include enabling playback of urgent sounds, such as smoke alarms. Playback of urgent sounds may promote safety in the case one or more people are present in away mode (e.g., if the away mode is inadvertently set).

In further examples, the configurations 764d may include re-directing urgent sounds. For instance, certain sounds (e.g., fire alarms and/or burglar alarms) may be re-directed from interior zones to exterior zones, which may facilitate notifying neighbors or emergency services of the fire or intrusion. An example of an exterior zone is the patio 101i (FIG. 1A).

As yet another example, the configurations 764d may include disabling other avenues of playing back audio on the playback system or other uses of the playback system. In particular, specific types of audio sources can be disabled such as physical line-in or audio input sources (e.g., audio line-in, 3.5 mm audio input, optical input). Other examples of audio sources that may be disabled include virtual line-in sources (e.g., AirPlay®).

In some examples, the configurations 764d include enabling one or more intrusion detection features. For instance, the playback device(s) 102 may enable intrusion detection via one or more microphones. With intrusion detection enabled, the playback device(s) 102 are configured to detect sounds indicative of intrusion (e.g., glass breaking). Further, when such sounds are detected, the playback devices 102 may notify the users. For instance, the media playback system 100 may push a notification to a user's mobile device (e.g., via a cloud service, such as a platform cloud service).

The playback device(s) 102 may be configured to switch from operating in one of the other modes 760 to operating in the away mode 760d when occurrence of one of the away mode trigger conditions 766d is detected. The away mode triggers 766d are representative of trigger conditions that may be suitable for the exemplary away mode 760d, and should not be considered limiting. Exemplary away modes may include additional or fewer trigger conditions. Yet, at the same time, exemplary trigger conditions should be reflective of conditions that are suitable for entering the away mode 760d and its attendant configurations 764d.

The playback device(s) may cause the change in operation mode to propagate to other systems. For example, in response to playback device(s) 102 changing the mode to operate in away mode, the media playback system may transmit a message to other systems (e.g., a home security system) over a network interface indicating that the media playback system is the away mode, and the other systems may perform actions (e.g., turn on home monitoring) in response to the change to away mode.

The away mode trigger conditions 766d may include detecting that users are not present in proximity to the media playback system 100. As described above in more detail, the media playback system 100 may detect user presence via any suitable technique, including the example techniques noted above. The media playback system 100 may utilize a timeout period. For instance, elapsing of a timeout period (e.g., 10 minutes) with no user presence detected may be configured as occurrence of an away mode trigger condition 766d.

Other away mode trigger conditions 766d may include user input to set or schedule the do-not-disturb mode 760c. For instance, on the way out the door, a user may speak the voice input “Set away mode.” Since the voice input did not specify target playback device(s) 102, this voice input may be considered to set away mode on all playback devices 102 in the media playback system 100. As another example, a user may set away mode while at home or away using a GUI on any of the control devices 104, or the control device 104 may use geo-location or geo-fencing to determine the user has left the home and change the media playback system 100.

In yet another example, the media playback system 100 may determine that a particular playback device 102 (e.g., portable playback device) is not located at home and turn on away mode. The determination may be made based on the portable playback device not being connected to a home wireless network and/or the portable playback device being connected to a control device 104 that is outside of the home based on geo-location. For example, an application on the control device can be connected to (e.g., over Bluetooth) or controlling the portable playback device, and the control device can determine that its location is outside of the home and that the portable playback device is nearby based on an active connection with the portable playback device.

Yet further, the away mode trigger conditions 766d may include events in a user's calendar. For instance, if the user has their office location set at home (e.g., because they work from home in the office 101e and sets out-of-office, this user input may trigger the media playback system 100 to set away mode on the playback devices 102 in the media playback system 100 (perhaps when set in combination with other conditions, such as inactivity on the media playback system 100). As another example, a user may put an event in their calendar with a location field set to another location (e.g., camping in the UP, Location=“Isle Royale National Park”). In such an example, the time and date of this appointment may be configured as an away mode trigger condition 766d.

FIG. 7E illustrates an example off mode 760e. In contrast to the modes 760a-c, the off mode 760d is intended to be utilized when the user(s) desires to turn the playback device(s) 102 into an off state. To implement the off mode 760e, the playback device(s) 102 apply a set of configurations 764e. The set of configurations 764e are representative, and should not be considered limiting. Exemplary off modes may include additional or fewer configurations. Yet, at the same time, exemplary configurations should further the use case of placing the playback device(s) 102 into an off state.

The configurations 764e may include disabling or hibernating various components of the playback device(s) 102. For instance, the configurations 764e may include putting the processor(s) 222 into a deep hibernate mode (FIG. 2A). In contrast to a complete power-down, the deep hibernate mode may be quicker to transition into another mode, as certain states may be maintained in the deep hibernate mode. Further, the configurations 764e may include disabling one or more radios, such as the radio(s) of the wireless network interface 225 (FIG. 2A). Yet further, the configurations 764e may include disabling one or more LEDs, such as LEDs to indicate power or other activity (such as microphone enable/disable).

Similar to the other modes 760, the playback device(s) 102 may be configured to switch from operating in one of the other modes 760 to operating in the off mode 760e when occurrence of one of the off mode trigger conditions 766e is detected. The off mode triggers 766e are representative of trigger conditions that may be suitable for the exemplary off mode 760e, and should not be considered limiting. Exemplary off modes may include additional or fewer trigger conditions. Yet, at the same time, exemplary trigger conditions should be reflective of conditions that are suitable for entering the off mode 760e and its attendant configurations 764e.

The off mode trigger conditions 766e may include user input to set the off mode. For instance, the playback device(s) 102 may be configured to respond to a user input to a particular button or touch control as occurrence of an off mode trigger condition 766e. In other examples, the off mode trigger conditions 766e may include expiration of a timeout period since receiving user input.

This timeout period may be set at a relatively longer time period as compared with the other timeout periods. For instance, the timeout period may be greater than 1 day (e.g., a week). Certain types of playback devices 102, such as portable, battery-powered playback devices 102, may have relatively shorter timeout periods.

FIG. 7F illustrates an example guest mode 760f. In contrast to the other modes, the guest mode 760f is intended to be utilized when one or more guest users are controlling the media playback system 100 using guest control devices. A guest may temporarily control the media playback system using a guest control interface on a mobile device (i.e., a guest control device 104). The determination of whether a user is a guest may be based on whether the guest control device is logged into an account authorized with the media playback system 100. The media playback system can identify all control devices which are not logged into an authorized account as guest control devices. Example techniques for guest access are described in U.S. Pat. No. 9,977,591 filed Apr. 26, 2013, and titled “Systems, Methods, Apparatus, and Articles of Manufacture to Provide Guest Access,” which is herein incorporated by reference in its entirety. Further example techniques for guest access are described in U.S. application Ser. No. 16/372,014 filed on Apr. 1, 2019, and titled “Access Control Techniques for Media Playback Systems,” which is also incorporated herein by reference in its entirety.

To implement the guest mode 760f, the playback device(s) 102 apply a set of configurations 764f. The set of configurations 764f are representative, and should not be considered limiting. Exemplary guest modes may include additional or fewer configurations. Yet, at the same time, exemplary configurations should further the use case of control by a guest user.

The configurations 764f may include suppressing playback of certain important sounds, such as notifications including personal information. For instance, the media playback system 100 may disable notifications from certain sources (e.g., certain cloud services) that are associated with personal information. Further, the media playback system 100 may disable notifications from certain smart devices that may be associated with personal information.

The configurations 764f may also include prohibiting modification of system settings. That is, the media playback system 100 may disable modification of certain system settings, such as configured audio sources including physical and virtual audio sources, zone configurations, voice assistant configurations, and the like, which prevents modification of these settings by the guest user(s). Further, the media playback system 100 may disable voice assistants (or certain functions thereof). For example, the media playback system 100 may disable all commands via voice assistant except for playback related commands.

Similar to the other modes 760, the playback device(s) 102 may be configured to switch from operating in one of the other modes 760 to operating in the guest mode 760f when occurrence of one of the guest mode trigger conditions 766f is detected. The guest mode triggers 766f are representative of trigger conditions that may be suitable for the exemplary guest mode 760f, and should not be considered limiting. Exemplary guest modes may include additional or fewer trigger conditions. Yet, at the same time, exemplary trigger conditions should be reflective of conditions that are suitable for entering the guest mode 760f and its attendant configurations 764f.

In examples, the guest mode trigger conditions 766f include detection of control by a guest control device. That is, the playback devices 102 may be configured to respond to connection of a guest (or unrecognized) control device as a guest mode trigger conditions 766f. The media playback system 100 may maintain or have access to identifying information (e.g., MAC addresses) of known or registered control devices 104. Alternatively, host control devices 104 may have a registered user profile of the media playback system 100, which is used to identify the host control devices 104 to the playback device(s) 100 (e.g., via an access or authorization token). Connection by control devices 104 without identification, or with temporary guest tokens, may be considered guest mode trigger conditions 766f.

In further examples, a user may trigger guest mode on one or more playback devices 102 by setting or scheduling the modes via user input. As noted above, example user interfaces include GUIs on the control device 104 and/or VUIs on the NMDs 103. Other examples are possible as well.

b. Switching Between Room Sound Modes

As noted above, the playback device(s) 102 may switch between room sound modes 760 when occurrence of one or more trigger conditions 766 is detected. In some example implementations, the room sound modes 760 are non-contemporary. That is, a playback device 102 can only operate in only one mode at a time. Further, when multiple playback devices 102 are in a zone group (FIG. 3A) or bonded zone (FIGS. 3B-3D), the grouped playback devices operate in the same mode. For instance, the bonded zone of playback devices 102a, 102b, and 102j in the den 101d operate together in one mode at a time.

As another example, if the user creates a zone group including the kitchen 101h and the dining room 101g, the resulting zone group operates together in one mode. If the constituent zones of a zone group are in different modes when the zone group is formed, the zone group may select a single mode to operate in (e.g., the mode of the zone group coordinator, the most-recently selected mode in the zone group, a manually-selected mode, or an automatically-selected mode). Alternatively, forming a group may trigger the constituent zones to switch to a particular mode (e.g., a foreground mode).

In some example implementations, zones within a zone group may be operating in different modes. For example, in the example the zone group above, the kitchen 101h may be in the background mode and the dining room 101g is in foreground mode. Where the modes overlap, the multiple zones in a zone group may output audio similarly. However, where the modes differ, the multiple zones may output audio differently based on their respective modes. For example, continuing the above example the kitchen 101h may duck audio frequencies corresponding to the human voice while the dining room 101g does not perform such ducking.

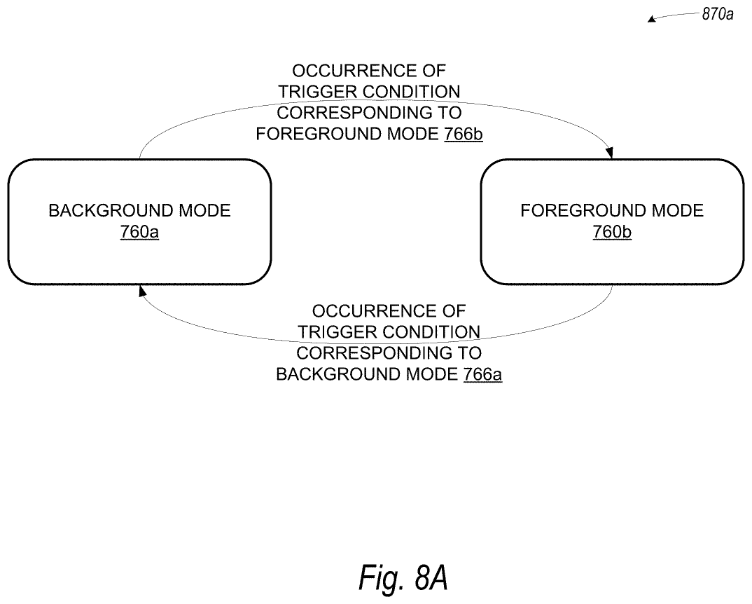

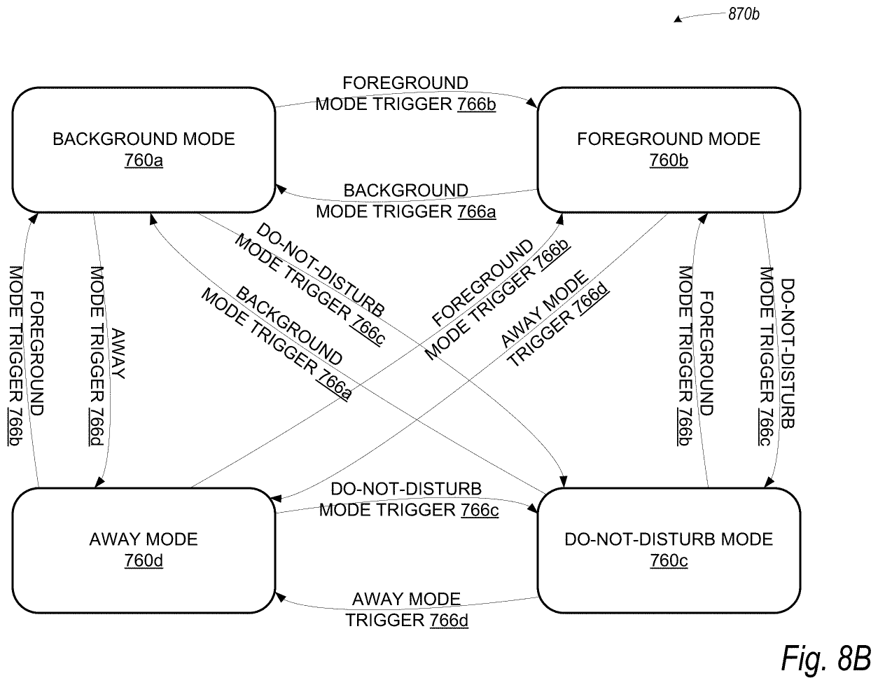

FIG. 8A shows a state diagram 870a illustrating an example where playback device(s) 102 are operable in two sound modes, the background mode 762a and foreground mode 762b. As shown in FIG. 8A, when occurrence of a trigger condition corresponding to the foreground mode 760b is detected (i.e., a trigger condition 766b), the playback device(s) 102 switch from operating in the background mode 762a to operating in the foreground mode 760b. Conversely, when occurrence of a trigger condition corresponding to the background mode 760a is detected (i.e., a trigger condition 766a), the playback device(s) 102 switch from operating in the foreground mode 762b to operating in the background mode 760a.

As another example, FIG. 8B shows a state diagram 870a that illustrates an example where playback device(s) 102 are operable in four sound modes, the background mode 762a and foreground mode 762b. As shown in FIG. 8B, when occurrence of a trigger condition corresponding to the background mode 760a is detected (i.e., a trigger condition 766a), the playback device(s) 102 may switch from operating in one of the other noncontemporary modes to operating in the background mode 760a. Similarly, when occurrence of a trigger condition corresponding to the foreground mode 760b is detected (i.e., a trigger condition 766b), the playback device(s) 102 may switch from operating in one of the other noncontemporary modes to operating in the foreground mode 760b. Further, when occurrence of a trigger condition corresponding to the do-not-disturb mode 760c is detected (i.e., a trigger condition 766c), the playback device(s) 102 may switch from operating in one of the other noncontemporary modes to operating in the do-not-disturb mode 760c. Yet further, when occurrence of a trigger condition corresponding to the away mode 760d is detected (i.e., a trigger condition 766d), the playback device(s) 102 may switch from operating in in one of the other noncontemporary modes to operating in the away mode 760d.

These concepts may extend to implementations where the playback device(s) 102 are operable in addition or fewer room sound modes 760. For instance, the playback device(s) 102 may be operable in all six of the room sound modes 760a-f illustrated in FIGS. 7A-7F. Alternatively, the playback device(s) 102 may be operable in two or more different sound modes, perhaps in addition to one or more of the example room sound modes 760a-f illustrated in FIGS. 7A-7F.

In an example, the playback device(s) 102 are further operable in a first mode where the room sound modes are disabled. In this mode, the playback device(s) 102 do not transition between modes nor apply configurations associated with the respective mode. Instead, the playback device(s) 102 function as if the playback device(s) 102 were not operable in one of a plurality of room sound modes. Conversely, in this example, the playback device(s) 102 are further operable in a second mode where the room sound modes are enabled. These two modes should not be considered room sound modes, but rather different modes that govern whether operation in the room sound modes is enabled or disabled.

In some instances, certain room sound modes may be disabled when certain conditions are met. For example, during a particular time period (e.g., night time, between 11 pm and 7 am), foreground and background mode may be disabled to limit audio playback during sleeping time periods. As another example, once the playback device is operating in away mode, all other modes may be disabled until an authorized user returns home. The media playback system can determine that an authorized user has returned by, for example, the user entering a password or PIN, logging into an account associated with the media playback system, the media playback system connecting to a host control device, or the presence of some other device as a proxy for a user's presence (e.g., smart watch of a user). After the media playback system has determined that a user has returned home, any restrictions on available sound modes can be removed.

In some aspects, the media playback system may determine the presence of a device associated with user by authenticating the control device with the media playback system through an exchange of audio tones. For example, the control device may cause one or more playback devices to play back ultrasonic or near-ultrasonic (e.g., 18-20 kHz) tones encoded with data (e.g., PIN, serial number, identifier). The control device can decode the audio tones to obtain the data and use the data to determine that the control device is a host control device. As another example, the control device may playback the audio tone and cause one or more mic-enabled playback devices to receive an audio data encoded with data. The playback devices may determine that the control device is a host control device based on the data decoded from the audio tones.

c. Propagating Events Corresponding to Occurrence of Trigger Conditions

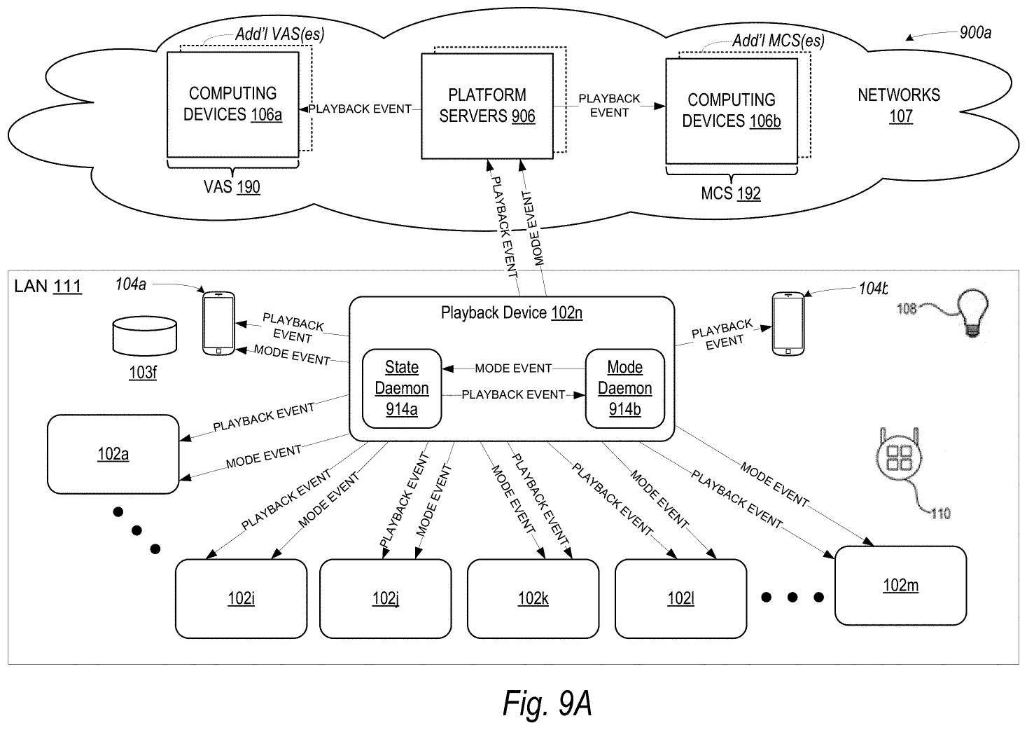

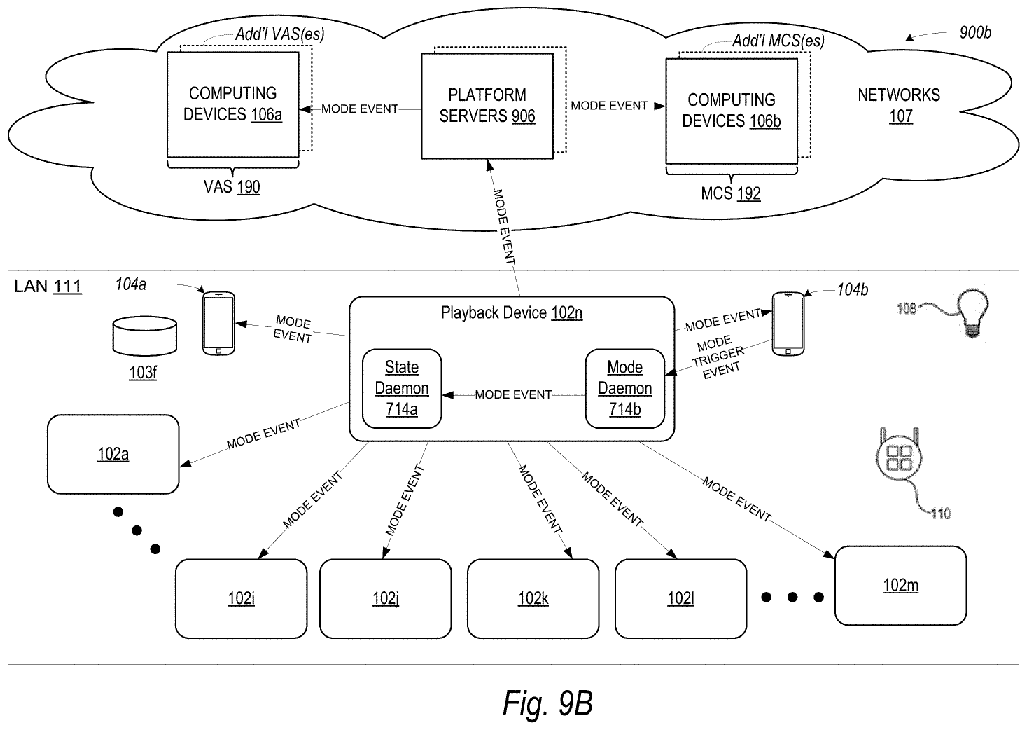

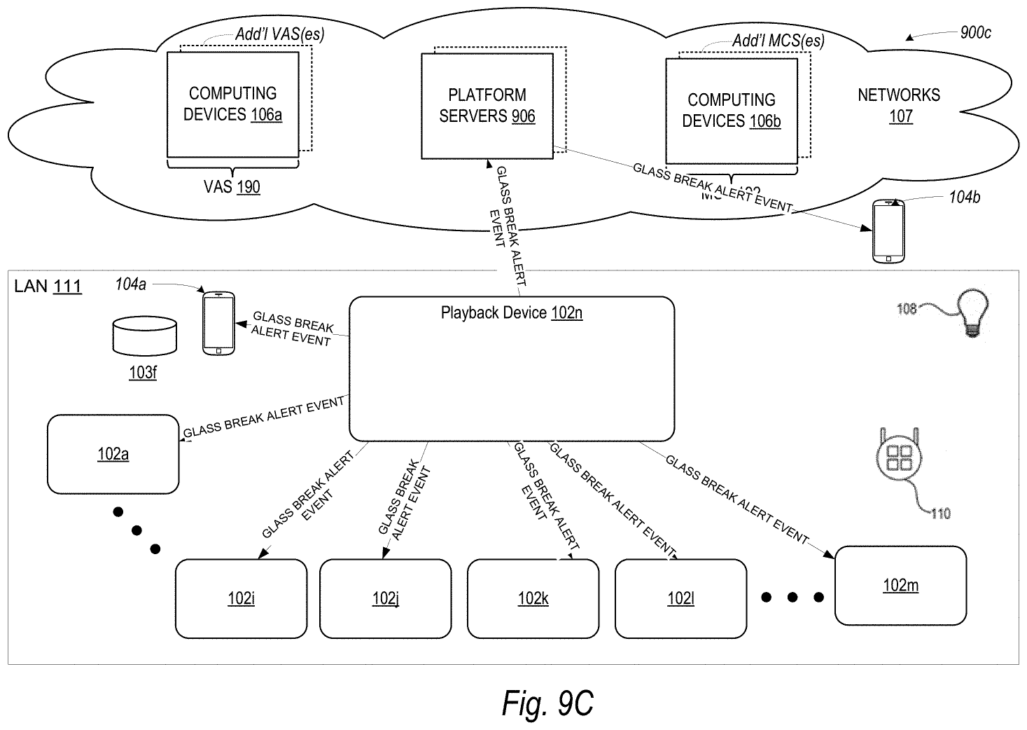

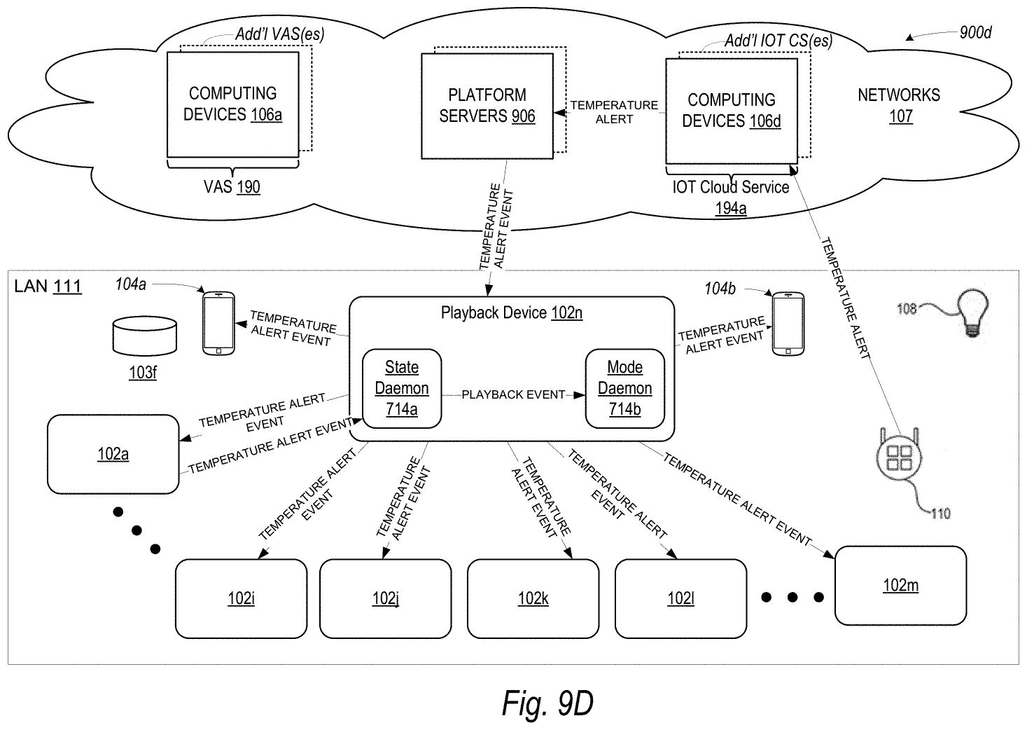

FIG. 9A-9D are a functional block diagrams of the media playback system 100 which illustrate an example architecture 900 to facilitate example propagation (e.g., messaging) of events corresponding to trigger conditions 766. As shown in FIGS. 9A-9D, occurrence of a mode trigger condition 766 may be detected internally by a playback device 102 or externally by another device integrated with the media playback system 100 (e.g., another playback device 102, a IOT device, or one or more computing devices 106 in the cloud), among other examples. The triggering mechanisms illustrated in FIGS. 9A and 9D are intended to be representative of exemplary triggering in the media playback system 100.

In various examples, occurrence of a mode trigger condition 766 may be detected internally by a playback device 102 operable in a plurality of room sound modes. For instance, a playback device 102 may maintain state information representing various states of the playback device. A change to one (or more) of these states may cause the playback device 102 to generate an event corresponding to occurrence of a trigger condition 766 corresponding to a given mode 760. The playback device 102 is configured to switch room sound modes based on this event.

To illustrate, FIG. 9A shows the playback device 102n. Playback 102n is a given one of the playback devices 102 that is configured to be operable in a plurality of room sound modes 760 which is described for the purposes of illustration. Other playback devices 102a-m in the media playback system 100 may be configured to implement similar functionality.

The playback device 102n includes a state daemon 914a, which may be implemented as part of the software components 214 (FIG. 2A). The state daemon 914a may be configured to detect occurrence of mode trigger conditions 766 and responsively switch room sound modes 760 on the playback device 102n. In one aspect, the state daemon 914a may be configured to generate events when state information is changed on the playback device 102n. In another aspect, the state daemon 914a may be implemented in the cloud (e.g., using the platform servers 906)

Such events may propagate data to subscribers. In an example, various entities may subscribe to a namespace, which configures the entity to receive events generated in that namespace. For instance, as shown in FIG. 9A, a mode daemon 914b may subscribe to a playback namespace, which causes the mode daemon 914b to receive events when status information is changed in the playback namespace. The event may be propagated locally on the playback device 102n via any suitable mechanism, such as an inter-process communication (IPC) mechanism.

When the mode daemon 914b receives the event, the mode daemon 914b may determine whether the state change represented by the event corresponds to occurrence of a mode trigger 766. For instance, the state daemon may generate a playback event in the playback namespace when changing audio content. The mode daemon 914b may receive data representing the playback event, and determine that the playback device 102n has transitioned from explicitly-selected content to auto-playing content. This determination amounts to detection that a background mode trigger 766a has occurred. The mode daemon 914b may then cause the playback device 102n to switch from operating in one of the other room sound modes to operating in the background mode 760a.

As shown in FIG. 9A, this event may be propagated via the LAN 111 and/or the networks 107 to other subscribers to the playback namespace. Such propagation may assist in keeping the media playback system 100 and other integrated devices up-to-date with the system status. Additional details are described above in connection with section II.

Additionally, or alternatively, the playback device 102n (perhaps via the mode daemon 914b) may generate a mode event when the playback device switches operating modes. Subscribers to a namespace (e.g., a mode namespace) may receive this event, and responsively update their corresponding status information to indicate that the current mode 760 of the playback device 102n.

In an example, the playback device 102n is in a synchrony group such as a bonded zone or a zone group with one or more additional playback devices 102. As noted above, playback devices 102 in a synchrony group may operate together in the same sound mode. In such an example, the playback device 102n may cause the additional playback devices 102 in the synchrony group to switch operating modes to maintain consistency with the playback device 102n.

For instance, the additional playback devices 102 in the synchrony group are subscribers to the mode namespace. In such examples, receiving the mode event, and responsively update their state information. Since they are in the synchrony group with the playback device 102n, this update causes the additional playback devices 102 to update their respective modes. Alternatively, the playback device 102n may send data representing instructions to change modes to the additional playback devices 102 to cause them to switch sound modes. As another example, the playback device 102n may operate as a central hub and manage mode changes for all devices within a home including smart home devices (e.g., home monitoring system, thermostat, etc.). Other examples are possible as well.

In some cases, the playback devices 102 integrate with one or more platform servers 906. The platform servers 906 may provide a platform service that supports the media playback system 100. Like the playback devices 102, the one or more platform servers 906 may maintain state information indicating the current state of each playback device 102 in the media playback system 100. In providing a cloud-based platform service, the one or more platform servers 906 may operate as a cloud-based hub for a plurality of media playback systems 100 (e.g., with unique household identifiers, which may be registered to different users and/or located in different households), as well as other types of “smart home” systems and platforms. Alternatively, instead of integrating with the platform servers 906, the playback device(s) 102 may integrate directly with computing devices of other cloud services (e.g., the computing devices 106a and/or the computing devices 106b).

FIG. 9B illustrates an example where occurrence of a mode trigger is detected on the control device 104b. For instance, the control device 104b may detect user input via a control interface (e.g., the control interfaces 540) to control the playback device 102n. When this user input, corresponds to a mode trigger 766, the control device 104b may generate a mode trigger event and propagate the event to subscribers of a mode trigger namespace (e.g., the mode daemon 914b, as shown in FIG. 9B).

Based on receiving this event, the playback device 102n may switch from operating in one of the other room sound modes 760 to operating in the particular room sound mode 760 associated with the mode trigger 766. Similar to FIG. 9A, the playback device 102n (perhaps via the mode daemon 914b) may generate a mode event when the playback device switches operating modes. Subscribers to a namespace (e.g., a mode namespace) may receive this event, and responsively update their corresponding status information to indicate that the current mode 760 of the playback device 102n.

FIG. 9C illustrates an example where the playback devices 102a-n are operating in the away mode 760d. As described in connection with FIG. 7D, the configurations 764d may include enabling intrusion detection. In the FIG. 9C example, intrusion detection using respective microphones 222 is enabled on the playback devices 102a-n.

In an example, the playback devices 102n detects a glass break (e.g., of the windows in the office 101e), and generates a glass break alert event. Similar to the other events, the glass break alert event is pushed to subscribers (e.g., of an alert namespace). Based on receiving such an event, the playback devices 102a-n may be configured to perform one or more actions, such as playing back an alarm sound at a pre-defined volume level.

Further, the media playback system 100 may be configured to propagate events (perhaps in the form of push notifications) to control devices 104. When the control devices 104 are connected to the LAN 111, the playback device 102n may propagate the event locally using the LAN 111, as illustrated with the control device 104a. Conversely, when the control devices 104 are not connected to the LAN 111, the playback device 102n may propagate the event via the platform servers 906 using the networks 107, as illustrated with the control device 104b. Other examples are possible as well.

In an example, other IOT devices in the household, such as smart doorbells, thermostats, or smoke alarms, may similar generate events in the alert namespace. Alternatively, such IOT devices may generate events or other messaging according to one or more APIs. Data representing alerts, alarms, and notifications generated by IOT devices may be passed over the LAN 111 or the networks 107 to the media playback system 100.

To illustrate, FIG. 9D illustrates an example where the smart thermostat 110 generates a temperature alert (e.g., for a low temperature, as might occur when a furnace in the household is malfunctioning). In this example, the smart thermostat 110 communicates with one or computing devices 106d of a IOT cloud service 194a. The IOT cloud service 194a is represented of a cloud service operated in support of smart thermostats and/or other IOT devices by a single manufacturer, or by multiple manufacturers (e.g., according to a standard or partnership).

In the FIG. 9D example, data representing the temperature alert is communicated via the LAN 111 and the networks 107 to the computing devices 106d. In turn, the computing devices 106d send data representing the temperature alert to the platform servers 906.

The platform servers 106 generate a temperature alert event and propagate the event to subscribers of an alerts namespace (e.g., the playback devices 102a-n) and/or the control devices 102n. In the FIG. 9D example, the playback device 102n operates as a point-of-contact between the platform servers 906 and the rest of the media playback system 100 to facilitate propagation of the event within the media playback system 100, as shown in FIG. 9D. Alternatively, the platform servers 906 may communicate directly with subscribers. Yet further, in other examples, alert events may be generated locally (e.g., by the playback device 102n or the thermostat 110) or elsewhere in the cloud (e.g., by the computing devices 106a).

As noted above, FIGS. 9A-9D are intended to be representative of internal and external trigger detection within the media playback system 100. Many variations are consistent with these examples. Further, the media playback system 100 may integrate with many types of IOT devices, not just the example TOT devices illustrated in FIGS. 9A-9D as well as elsewhere throughout the disclosure.

d. Example Graphical User Interfaces to Set/Schedule Room Sound Modes

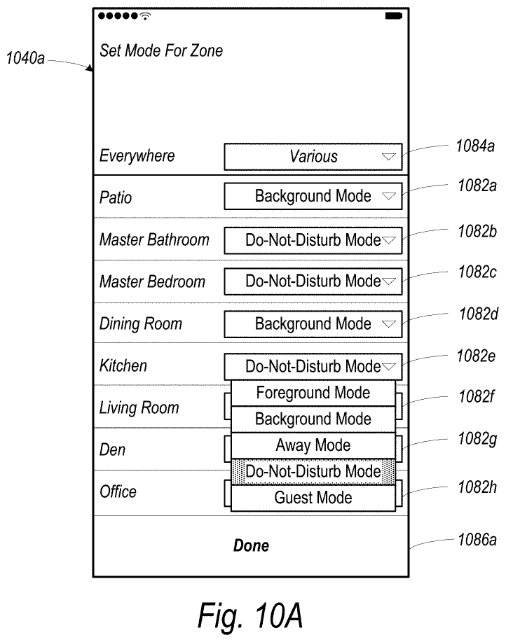

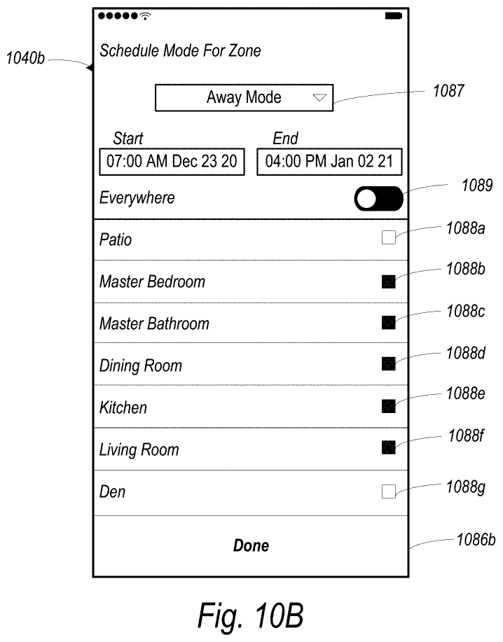

FIGS. 10A and 10B present example controller interfaces 1040a and 1040b, which may be provided on a touch-screen display or other physical interface configured to provide various graphical controller interfaces, similar to the controller interfaces 540a and 540b (FIGS. 5A and 5B).

The controller interface 1040a shown in FIG. 10A includes controls to set a room sound mode 760 in the zones 101 of the media playback system 100. In particular, the controller interface 1040a includes a selectable control 1082a, 1082b, 1082c, 1082d, 1082e, 1082f, 1082g, and 1082h to set the sound mode 760 in the patio 101i, master bedroom 101b, master bathroom 101a, dining room 101g, kitchen 101h, living room 101f, den 101d, and office 101e. The selectable controls 1082 indicate the current sound mode of each zone using text in the respective controls, as shown (e.g., the patio 101i is currently in the background mode 760a). On the controller interface 1040a, controls to set mode in additional zones in the media playback system 100 can be shown by scrolling.

As shown, the selectable control 1082e is expanded (e.g., via a touch selection) to show the room sound modes that can be set in the kitchen 101h, for instance. In this control, a mode can be set by selecting the text indicating the respective mode. These controls should be considered representative. Other types of controls to set sound modes may be implemented as well.

The controller interface 1040a shown in FIG. 10A also includes a selectable control 1084a that is selectable to set the room sound mode 760 everywhere in the media playback system 100. When various zones in the media playback system 100 are operating in different sound modes, the controller interface 1040a may indicate this status (e.g., using “Various” text as shown in FIG. 10A). Other examples are possible as well.

The controller interface 1040a further includes a selectable control 1086a, that when selected, closes the controller interface 1040a (and displays another control interface, such as a settings control interface, or one of the controller interfaces 540, among other examples). In an example, selection of the selectable control 1086a sets the mode 760 for each zone 101 (or each zone 101 that was modified), perhaps by modifying state information associated with the respective zone 101. Alternatively, the modes 760 are set when selections are made in the controls 1082. Such user input may be considered a trigger condition 766, as described in connection with FIGS. 7A-7F.

The controller interface 1040b shown in FIG. 10B includes controls to schedule a room sound mode 760 in one or more zones 101 of the media playback system 100. The controller interface 1040b includes selectable controls 1087 to set room sound mode 760 and a start and/or end time and date for selected sound mode 760 to start and/or stop. The controller interface 1040b also includes selectable controls 1088a-g to selects the patio 101i, master bedroom 101b, master bathroom 101a, dining room 101g, kitchen 101h, living room 101f, and den 101d for inclusion in the schedule. Alternatively, the selectable control 1089 to set the schedule in all zones 101. Similar to the selectable control 1086a of the control interface 1040a, the control interface 1040b also includes a selectable control 1086b. Within examples, once a schedule is set, the media playback system may generate a trigger event or otherwise detect occurrence of a trigger condition 766 when the scheduled mode change is scheduled to occur.

e. Room Sound Modes and Portable Playback Devices

In some examples, a portable playback device 102 may implement room sound modes. In addition to other example mode switching techniques described above, a portable playback device may switch between modes based on movement. In particular, as a portable playback device is moved into proximity of a first zone (e.g., into a first room) within the media playback system 100, the portable playback device may switch to the same room sound mode as other playback devices 102 in that first zone. Then, when moved again to a second zone within the media playback system 100, the portable playback device may switch to the same room sound mode as other playback devices 102 in that second zone. In this way, the portable playback device may automatically take on the characteristics of a particular room sound mode when in the same room as other playback devices operating in that mode.

A portable playback device may detect that it is in a particular zone or room using any suitable technique. For instance, using one or more microphones, the portable playback device may detect sound output from playback devices in a zone and using that detected sound, determine that the portable playback device is in that zone. Alternatively, the playback devices in a zone may detect the presence of a portable playback devices. Example techniques related to detection of playback devices in a zone are described in U.S. Pat. No. 9,329,831 filed on Feb. 25, 2015, and titled “Playback Expansion,” which is incorporated by reference herein in its entirety.

### IV. Example Methods

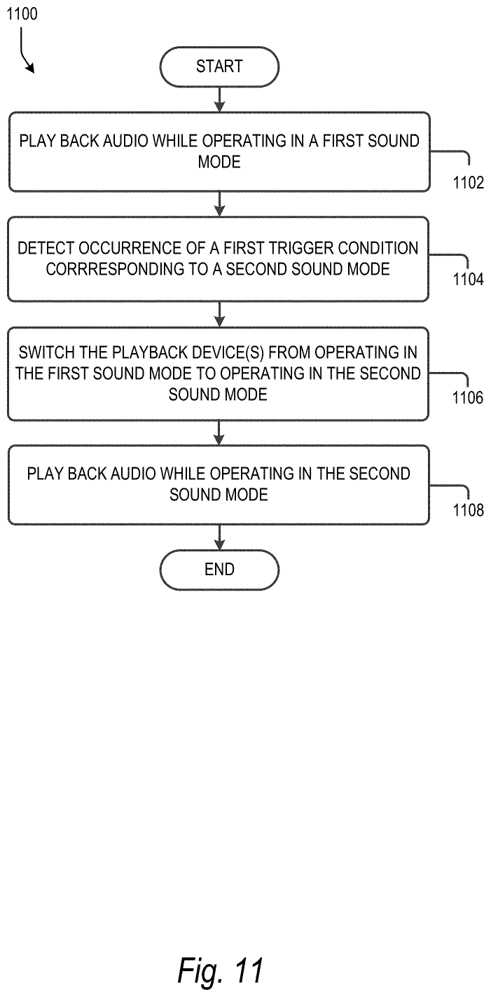

FIG. 11 is a flow diagram showing an example method 1100 to operate in and switch between room sound modes. The method 1100 may be performed by one or more playback device(s) 102. Alternatively, the method 1100 may be performed by any suitable device or by a system of devices, such as the NMDs 103, control devices 104, computing devices 105 computing devices 106, or by smart IOT devices (such as the smart illumination device 108 or smart thermostat 110). For the purposes of illustration, certain features are described as being performed by the playback device(s) 102.

At block 1102, the method 1100 involves playing back audio while operating in a first sound mode. For instance, one or more playback device(s) 102 operable in a plurality of noncontemporary sound modes may play back audio via one or more speakers while operating in the background mode 760a. In the first sound mode, the playback device(s) 102 are configured with one or more configurations. For instance, the playback device(s) 102 may be configured to duck frequencies of the audio corresponding to human voice when operating in the background mode 760a and voice activity is detected, as described in connection with the configurations 764a (FIG. 7A).

At block 1104, the method 1100 involves detecting occurrence of a first trigger condition corresponding to the first sound mode. For example, the playback device(s) 102 may detect occurrence of a first trigger condition corresponding to the foreground mode 760b. Example trigger conditions corresponding to the foreground mode 760b include the foreground mode triggers 766b (FIG. 7B).

For instance, the first trigger condition 766b may include user activity. In such examples, detecting occurrence of the first trigger condition corresponding to the foreground mode 760b may include receiving, via a network interface, data indicating that a control application on a control device is receiving user input to control the media playback system. Based on receiving the data indicating that the control application on the control device is receiving the user input, determine that the first trigger condition has occurred. Further examples are described in connection with FIGS. 9A-9D and 10A-B.

At block 1106, the method 1100 involves switching the playback device(s) from operating in the first sound mode to operating in the second sound mode. For instance, the playback device(s) 102 may switch from operating in the background mode 760a to operating in the foreground mode 760b based on detecting the occurrence of the first trigger condition corresponding to the foreground mode (FIG. 8A).

At block 1108, the method involves playing back audio while operating in the second sound mode. For instance, the playback device(s) 102 may play back audio via one or more speakers while operating in the foreground mode 760b. In the second sound mode, the playback device(s) 102 are configured with one or more configurations. For instance, the playback device(s) 102 may be configured to forego ducking frequencies of the audio corresponding to human voice when operating in the foreground mode 760b, as described in connection with the configurations 764b (FIG. 7B).

In further examples, the method 1100 involves switching from operating in one of the other noncontemporary modes to operating in a third sound mode. For instance, the playback device(s) 102 may switch from operating in one of the other noncontemporary modes to operating in the do-not-disturb mode 760c. While operating in the do-not-disturb mode, the playback device(s) 102 are configured to play back alerts from one or more cloud services and forego playback of other audio, as described in connection with the configurations 764c (FIG. 7C).

Within examples, the method 1100 involves switching back to one of the sound modes. For instance, while operating in the do-not-disturb mode 760c, the playback device(s) 102 may receive an instruction to play back particular audio content (e.g., explicitly-selected content). Based on receiving the instruction to play back the particular audio content, the playback device(s) 102 switch from operating in the do-not-disturb mode 760c to operating in the foreground mode 760b and play back the particular audio content via the one or more speakers while operating in the foreground mode 760b.

In some modes, the method 100 involves temporarily increasing a volume setting of the first playback device to a particular volume level when playing back urgent sounds and/or important sounds (FIGS. 7A-7E). For example, while operating in the do-not-disturb mode 760c, the playback device(s) 102 temporarily increase a volume setting of the playback device(s) 102 to a particular volume level when playing back the alerts from the one or more cloud services.

Within examples, the method 100 involves adjusting settings of one or more second playback devices when operation of the second playback devices is affecting operation by one or more first playback devices. For instance, while operating in the do-not-disturb mode 760c, one or more first playback devices 102 may detect, via at least one microphone, sound corresponding to playback by one or more second playback devices 102 above a threshold sound pressure level. The one or more first playback devices 102 may decrease a volume setting of the one or more second playback devices 102 until the detected sound corresponding to playback by one or more second playback devices 102 is below the threshold sound pressure level.

In further examples, the method 1100 may involve operating in another mode, such as the away mode 760d. For example, the playback device(s) 102 may switch from operating in one of the other noncontemporary modes to operating in the away mode 760d and then operate in the away mode 760d. While operating in the away mode, the playback device(s) 102 are configured to play back a mix of audio content at intervals to simulate usage of the media playback system, as described in connection with the configurations 764d (FIG. 7D). Further, while operating in the away mode, the playback device(s) 102 may be configured to select particular media items to include in the mix of audio content based on relatively lower royalty rates for the particular media items relative to other media items in a library of the media playback system.

Within examples, the method 1100 may involve further operations while operating in the another mode (e.g., the away mode 760d). For instance, while operating in the away mode 760d, the playback device(s) 102 may disable notifications configured in the media playback system 100 and/or disable scheduled playback configured in the media playback system 100. As another example, while operating in the away mode 760d, the playback device(s) 102 may disable one or more voice assistants and/or enable intrusion detection via at least one microphone.

In some examples, the method 1100 may involve playing back audio according to one or more equalizations while in multiple sound modes. For instance, while playing back audio in the background mode 760a, the playback device(s) 102 play back the audio according to one or more equalizations including at least one of (a) a calibration equalization and (b) a user-defined equalization. Similarly, while playing back audio in the foreground mode 760b, the playback device(s) 102 may play back the audio according to the one or more equalizations.

The method 1100 may further involve detecting a second trigger condition corresponding to one of the sound modes. For example, the playback device(s) 102 may detect occurrence of a second trigger condition corresponding to the foreground mode 760b, such as a volume increase (FIG. 7B). Based on detecting the occurrence of the second trigger condition corresponding to the foreground mode 760b, the playback device(s) 102 may switch from operating in one of the other noncontemporary modes to operating in the foreground mode 760b.

The method 1100 may further involve playing back audio from a playback queue. For instance, the method 100 may involve the playback device(s) 102 receiving data representing instructions to queue one or more first media items in the queue. The one or more first media items may be selected via a control application (e.g., on the control device(s) 104). While playing back a second media item that was automatically added to the queue after one or more first media items finished playback, the playback device(s) 102 may detect occurrence of a third trigger condition corresponding to the foreground mode 760b. The third trigger condition corresponding to the foreground mode may involve receipt, via the network interface, of data representing instructions to queue one or more third media items in the queue, where the one or more third media items were selected via the control application. Based on detecting the occurrence of the third trigger condition corresponding to the foreground mode 760b, the playback device(s) 102 switch from operating in one of the other noncontemporary modes to operating in the foreground mode 760b.

The method 1100 may further involve detecting occurrence of a first trigger condition corresponding to the first sound mode (e.g., the background mode 760a), such as a volume decrease, as described in connection with the background mode triggers 766a. Based on detecting the occurrence of the first trigger condition corresponding to the background mode 760a, the playback device(s) 102 switch from operating in one of the other noncontemporary modes to operating in the background mode 760a.

The method 1100 may also involve detecting occurrence of a second trigger condition corresponding to the first sound mode (e.g., the background mode 760a), such as an increase in a number of listeners in proximity to the first playback device, as described in connection with the background mode triggers 766a. Based on detecting the occurrence of the first trigger condition corresponding to the background mode 760a, the playback device(s) 102 switch from operating in one of the other noncontemporary modes to operating in the background mode 760a.

The method 1100 may further involve operating in another sound mode, such as the off mode 760e. In such examples, the method 1100 may involve the playback device(s) 102 switching from operating in one of the other noncontemporary modes to operating in the off mode 760e. Further, the method 1100 may involve operate in the off mode 760e. While operating in the off mode 760e, the playback device(s) 102 are configured with one or more configurations, such as (i) transitioning at least one processor in a hibernate mode, (ii) disabling one or more radios, and/or (iii) disabling LEDs, as described in connection with the configurations 764e (FIG. 7E).

The method 1100 may further involve operating in another sound mode, such as the guest mode 760f. In such examples, the method 1100 may involve the playback device(s) 102 switching from operating in one of the other noncontemporary modes to operating in the guest mode 760f. Further, the method 1100 may involve operate in the guest mode 760f. While operating in the guest mode 760f, the playback device(s) 102 are configured with one or more configurations such as (i) suppressing playback of personal alerts while permitting playback of emergency alerts, (ii) prohibiting modification of system settings while permitting modification of playback content and volume settings on the playback device(s) 102, and (iii) disabling one or more voice assistants, as described in connection with the configurations 764f (FIG. 7F).

Further variations and functions that may be performed as part of the method 1100 are described throughout this disclosure, including in the foregoing sections I, II, and III.

### CONCLUSION

The description above discloses, among other things, various example systems, methods, apparatus, and articles of manufacture including, among other components, firmware and/or software executed on hardware. It is understood that such examples are merely illustrative and should not be considered as limiting. For example, it is contemplated that any or all of the firmware, hardware, and/or software aspects or components can be embodied exclusively in hardware, exclusively in software, exclusively in firmware, or in any combination of hardware, software, and/or firmware. Accordingly, the examples provided are not the only way(s) to implement such systems, methods, apparatus, and/or articles of manufacture.

The specification is presented largely in terms of illustrative environments, systems, procedures, steps, logic blocks, processing, and other symbolic representations that directly or indirectly resemble the operations of data processing devices coupled to networks. These process descriptions and representations are typically used by those skilled in the art to most effectively convey the substance of their work to others skilled in the art. Numerous specific details are set forth to provide a thorough understanding of the present disclosure. However, it is understood to those skilled in the art that certain embodiments of the present disclosure can be practiced without certain, specific details. In other instances, well known methods, procedures, components, and circuitry have not been described in detail to avoid unnecessarily obscuring aspects of the embodiments. Accordingly, the scope of the present disclosure is defined by the appended claims rather than the forgoing description of embodiments.

When any of the appended claims are read to cover a purely software and/or firmware implementation, at least one of the elements in at least one example is hereby expressly defined to include a tangible, non-transitory medium such as a memory, DVD, CD, Blu-ray, and so on, storing the software and/or firmware.

The present technology is illustrated, for example, according to various aspects described below. Various examples of aspects of the present technology are described as numbered examples (1, 2, 3, etc.) for convenience. These are provided as examples and do not limit the present technology. It is noted that any of the dependent examples may be combined in any combination, and placed into a respective independent example. The other examples can be presented in a similar manner.

Example 1: A method to be performed in a media playback system comprising a first playback device operable in a plurality of noncontemporary modes, the method comprising: playing back audio via one or more speakers while operating in a background mode, wherein the first playback device is configured to duck frequencies of the audio corresponding to human voice when operating in the background mode; detecting occurrence of a first trigger condition corresponding to the foreground mode; based on detecting the occurrence of the first trigger condition corresponding to the foreground mode, switching the first playback device from operating in the background mode to operating in the foreground mode; and playing back the audio via one or more speakers while operating in the foreground mode, wherein the first playback device is configured to forego ducking when operating in the background mode.

Example 2: The method of Example 1, wherein the plurality of noncontemporary modes further comprise a do-not-disturb mode, and wherein method further comprises: switching from operating in one of the other noncontemporary modes to operating in the do-not-disturb mode, wherein, while operating in the do-not-disturb mode, the first playback is configured to (i) play back alerts from one or more cloud services and (ii) forego playback of other audio.

Example 3: The method of Example 2, further comprising: while operating in the do-not-disturb mode, receiving an instruction to play back particular audio content; and based on receiving the instruction to play back the particular audio content, (i) switching from operating in the do-not-disturb mode to operating in the foreground mode and (ii) playing back the particular audio content via the one or more speakers while operating in the foreground mode.

Example 4: The method of any of Examples 2-3, further comprising: while operating in the do-not-disturb mode, temporarily increasing a volume setting of the first playback device to a particular volume level when playing back the alerts from the one or more cloud services.

Example 5: The method of Example 2-4, further comprising: while operating in the do-not-disturb mode, detecting, via the at least one microphone, sound corresponding to playback by one or more second playback devices above a threshold sound pressure level; and decrease a volume setting of the one or more second playback devices until the detected sound corresponding to playback by one or more second playback devices is below the threshold sound pressure level.

Example 6: The method of any of Examples 1-5, wherein the plurality of noncontemporary modes further comprise an away mode, the method further comprising: switching from operating in one of the other noncontemporary modes to operating in the away mode; and operating in the away mode, wherein, while operating in the away mode, the first playback device is configured to play back a mix of audio content at intervals to simulate usage of the media playback system.

Example 7: The method of Example 6, wherein operating in the away mode comprises selecting particular media items to include in the mix of audio content based on relatively lower royalty rates for the particular media items relative to other media items in a library of the media playback system.

Example 8: The method of any of Examples 6-7, wherein operating in the away mode comprises while operating in the away mode: disabling notifications configured in the media playback system; and disabling scheduled playback in the media playback system.

Example 9: The method of any of Examples 6-8, wherein the first playback device comprises a network microphone device corresponding to one or more voice assistants, and wherein operating in the away mode comprises disabling the one or more voice assistants; and enabling intrusion detection via the at least one microphone.

Example 10: The method of any preceding Example, wherein playing back audio via one or more speakers while operating in the background mode comprises playing back the audio according to one or more equalizations comprising at least one of (a) a calibration equalization and (b) a user-defined equalization, and wherein playing back the audio via one or more speakers while operating in the foreground mode comprise playing back the audio according to the one or more equalizations.

Example 11: The method of any preceding Example, wherein the first playback device further comprises at least one microphone, wherein playing back audio via one or more speakers while operating in the background mode comprises receiving data indicating that voice activity is detected in a listening environment comprising the first playback device, and ducking frequencies of the audio corresponding to human voice when (i) operating in the background mode and (ii) voice activity is detected.

Example 12: The method of any preceding Example, wherein the first trigger condition corresponding to the foreground mode comprises user activity, wherein detecting the first trigger condition corresponding to the foreground mode comprises receiving, via a network interface, data indicating that a control application on a control device is receiving user input to control the media playback system; and based on receiving the data indicating that the control application on the control device is receiving the user input, determine that the first trigger condition has occurred.

Example 13: The method of any preceding Example, further comprising: detecting occurrence of a second trigger condition corresponding to the foreground mode, wherein the second trigger condition corresponding to the foreground mode comprises a volume increase; and based on detecting the occurrence of the second trigger condition corresponding to the foreground mode, switch the first playback device from operating in one of the other noncontemporary modes to operating in the foreground mode.

Example 14: The method of any preceding Example, wherein the first playback device is configured to play back audio content from a queue, and wherein the method further comprises: receiving, via a network interface, data representing instructions to queue one or more first media items in the queue, wherein the one or more first media items were selected via a control application; while playing back a second media item that was automatically added to the queue after one or more first media items finished playback, detect occurrence of a third trigger condition corresponding to the foreground mode, wherein the third trigger condition corresponding to the foreground mode comprises receipt, via the network interface, of data representing instructions to queue one or more third media items in the queue, wherein the one or more third media items were selected via the control application; and based on detecting the occurrence of the third trigger condition corresponding to the foreground mode, switching the first playback device from operating in one of the other noncontemporary modes to operating in the foreground mode.

Example 15: The method of any preceding Example, further comprising: detecting occurrence of a first trigger condition corresponding to the background mode, wherein the first trigger condition corresponding to the background mode comprises a volume decrease; and based on detecting the occurrence of the first trigger condition corresponding to the background mode, switch the first playback device from operating in one of the other noncontemporary modes to operating in the background mode.

Example 16: The method of any preceding Example, further comprising: detecting occurrence of a second trigger condition corresponding to the background mode, wherein the second trigger condition corresponding to the background mode comprises an increase in a number of listeners in proximity to the first playback device; and based on detecting the occurrence of the second trigger condition corresponding to the foreground mode, switching the first playback device from operating in one of the other noncontemporary modes to operating in the background mode.

Example 17: The method of any preceding Example, wherein the plurality of noncontemporary modes further comprise an off mode, and wherein the method further comprises: switching from operating in one of the other noncontemporary modes to operating in the off mode; and operating in the off mode, wherein, while operating in the off mode, the first playback is configured to (i) transition the at least one processor in a hibernate mode, (ii) disable one or more radios of the network interface; and (iii) disable LEDs on the first playback device.

Example 18: The method of any preceding Example, wherein the plurality of noncontemporary modes further comprise a guest mode, and wherein the method further comprises: switch from operating in one of the other noncontemporary modes to operating in the guest mode; and operating in the guest mode, wherein, while operating in the guest mode, the first playback is configured to (i) suppress playback of personal alerts while permitting playback of emergency alerts, (ii) prohibit modification of system settings while permitting modification of playback content and volume settings on the first playback device, and (iii) disable the one or more voice assistants.

Example 20: A tangible, non-transitory, computer-readable medium having instructions stored thereon that are executable by one or more processors to cause a system to perform the method of any one of Examples 1-18.

Example 21: A device comprising a network interface, one or more processors, and a tangible, non-tangible computer-readable medium having instructions stored thereon that are executable by the one or more processors to cause the system to perform the method of any of Examples 1-18.

Example 22: A system comprising a network interface, one or more processors, and a tangible, non-tangible computer-readable medium having instructions stored thereon that are executable by the one or more processors to cause the system to perform the method of any of Examples 1-18.

We claim:

1. A media playback system comprising a first playback device operable in a plurality of noncontemporary modes comprising a foreground mode and a background mode, wherein the first playback device comprises at least one microphone, a network interface, at least one processor and data storage including instructions that are executable by the at least one processor such that the first playback device is configured to:
play back audio via one or more speakers while operating in the background mode, wherein the first playback device is configured to duck frequencies of the audio corresponding to human voice when operating in the background mode;
detect occurrence of a first trigger condition corresponding to the foreground mode;
based on detecting the occurrence of the first trigger condition corresponding to the foreground mode, switch the first playback device from operating in the background mode to operating in the foreground mode; and
play back the audio via one or more speakers while operating in the foreground mode, wherein the first playback device is configured to forego ducking when operating in the background mode.

2. The media playback system of claim 1, wherein the plurality of noncontemporary modes further comprise a do-not-disturb mode, and wherein the instructions are executable by the at least one processor such that the first playback device is further configured to:
switch from operating in one of the other noncontemporary modes to operating in the do-not-disturb mode, wherein, while operating in the do-not-disturb mode, the first playback is configured to (i) play back alerts from one or more cloud services and (ii) forego playback of other audio.

3. The media playback system of claim 2, wherein the instructions are executable by the at least one processor such that the first playback device is further configured to:
while operating in the do-not-disturb mode, receive an instruction to play back particular audio content; and
based on receiving the instruction to play back the particular audio content, (i) switch from operating in the do-not-disturb mode to operating in the foreground mode and (ii) play back the particular audio content via the one or more speakers while operating in the foreground mode.

4. The media playback system of claim 2, wherein the instructions are executable by the at least one processor such that the first playback device is further configured to:
while operating in the do-not-disturb mode, temporarily increase a volume setting of the first playback device to a particular volume level when playing back the alerts from the one or more cloud services.

5. The media playback system of claim 2, wherein the instructions are executable by the at least one processor such that the first playback device is further configured to:
while operating in the do-not-disturb mode, detect, via the at least one microphone, sound corresponding to playback by one or more second playback devices above a threshold sound pressure level; and
decrease a volume setting of the one or more second playback devices until the detected sound corresponding to playback by one or more second playback devices is below the threshold sound pressure level.

6. The media playback system of claim 1, wherein the plurality of noncontemporary modes further comprise an away mode, and wherein the instructions are executable by the at least one processor such that the first playback device is further configured to:
switch from operating in one of the other noncontemporary modes to operating in the away mode; and
operate in the away mode, wherein, while operating in the away mode, the first playback device is configured to play back a mix of audio content at intervals to simulate usage of the media playback system.

7. The media playback system of claim 6, wherein the instructions that are executable by the at least one processor such that the first playback device is configured to operate in the away mode comprise instructions that are executable by the at least one processor such that the first playback device is configured to:
select particular media items to include in the mix of audio content based on relatively lower royalty rates for the particular media items relative to other media items in a library of the media playback system.

8. The media playback system of claim 6, wherein the instructions that are executable by the at least one processor such that the first playback device is configured to operate in the away mode comprise instructions that are executable by the at least one processor such that the first playback device is configured to:
while operating in the away mode:
(i) disable notifications configured in the media playback system; and
(ii) disable scheduled playback in the media playback system.

9. The media playback system of claim 6, wherein the first playback device comprises a network microphone device corresponding to one or more voice assistants, and wherein the instructions that are executable by the at least one processor such that the first playback device is configured to operate in the away mode comprise instructions that are executable by the at least one processor such that the first playback device is configured to:
while operating in the away mode:
(i) disable the one or more voice assistants; and
(ii) enable intrusion detection via the at least one microphone.

10. The media playback system of claim 1, wherein:
the instructions that are executable by the at least one processor such that the first playback device is configured to play back audio via one or more speakers while operating in the background mode comprise instructions that are executable by the at least one processor such that the first playback device is configured to play back the audio according to one or more equalizations comprising at least one of (a) a calibration equalization and (b) a user-defined equalization; and
the instructions that are executable by the at least one processor such that the first playback device is configured to play back the audio via one or more speakers while operating in the foreground mode comprise instructions that are executable by the at least one processor such that the first playback device is configured to play back the audio according to the one or more equalizations.

11. The media playback system of claim 1, wherein the first playback device further comprises at least one microphone, wherein the instructions that are executable by the at least one processor such that the first playback device is configured to play back audio via one or more speakers while operating in the background mode comprise instructions that are executable by the at least one processor such that the first playback device is configured to:
receive data indicating that voice activity is detected in a listening environment comprising the first playback device; and
duck frequencies of the audio corresponding to human voice when (i) operating in the background mode and (ii) voice activity is detected.

12. The media playback system of claim 1, wherein the first trigger condition corresponding to the foreground mode comprises user activity, and wherein the instructions that are executable by the at least one processor such that the first playback device is configured to detect the first trigger condition corresponding to the foreground mode comprise instructions that are executable by the at least one processor such that the first playback device is configured to:
receive, via the network interface, data indicating that a control application on a control device is receiving user input to control the media playback system; and
based on receiving the data indicating that the control application on the control device is receiving the user input, determine that the first trigger condition has occurred.

13. The media playback system of claim 1, wherein the instructions are executable by the at least one processor such that the first playback device is further configured to:
detect occurrence of a second trigger condition corresponding to the foreground mode, wherein the second trigger condition corresponding to the foreground mode comprises a volume increase; and
based on detecting the occurrence of the second trigger condition corresponding to the foreground mode, switch the first playback device from operating in one of the other noncontemporary modes to operating in the foreground mode.

14. The media playback system of claim 1, wherein the first playback device is configured to play back audio content from a queue, wherein the instructions are executable by the at least one processor such that the first playback device is further configured to:
receive, via the network interface, data representing instructions to queue one or more first media items in the queue, wherein the one or more first media items were selected via a control application;
while playing back a second media item that was automatically added to the queue after one or more first media items finished playback, detect occurrence of a third trigger condition corresponding to the foreground mode, wherein the third trigger condition corresponding to the foreground mode comprises receipt, via the network interface, of data representing instructions to queue one or more third media items in the queue, wherein the one or more third media items were selected via the control application; and
based on detecting the occurrence of the third trigger condition corresponding to the foreground mode, switch the first playback device from operating in one of the other noncontemporary modes to operating in the foreground mode.

15. The media playback system of claim 1, wherein the instructions are executable by the at least one processor such that the first playback device is further configured to:
detect occurrence of a first trigger condition corresponding to the background mode, wherein the first trigger condition corresponding to the background mode comprises a volume decrease; and
based on detecting the occurrence of the first trigger condition corresponding to the background mode, switch the first playback device from operating in one of the other noncontemporary modes to operating in the background mode.

16. The media playback system of claim 1, wherein the instructions are executable by the at least one processor such that the first playback device is further configured to:
detect occurrence of a second trigger condition corresponding to the background mode, wherein the second trigger condition corresponding to the background mode comprises an increase in a number of listeners in proximity to the first playback device; and
based on detecting the occurrence of the second trigger condition corresponding to the foreground mode, switch the first playback device from operating in one of the other noncontemporary modes to operating in the background mode.

17. The media playback system of claim 1, wherein the plurality of noncontemporary modes further comprise an off mode, and wherein the instructions are executable by the at least one processor such that the first playback device is further configured to:
switch from operating in one of the other noncontemporary modes to operating in the off mode; and
operate in the off mode, wherein, while operating in the off mode, the first playback is configured to (i) transition the at least one processor in a hibernate mode, (ii) disable one or more radios of the network interface; and (iii) disable LEDs on the first playback device.

18. The media playback system of claim 1, wherein the first playback device comprises a network microphone device corresponding to one or more voice assistants, wherein the plurality of noncontemporary modes further comprise a guest mode, and wherein the instructions are executable by the at least one processor such that the first playback device is further configured to:
switch from operating in one of the other noncontemporary modes to operating in the guest mode; and
operate in the guest mode, wherein, while operating in the guest mode, the first playback is configured to (i) suppress playback of personal alerts while permitting playback of emergency alerts, (ii) prohibit modification of system settings while permitting modification of playback content and volume settings on the first playback device, and (iii) disable the one or more voice assistants.

19. A method comprising to be performed by a media playback system comprising a first playback device operable in a plurality of noncontemporary modes comprising a foreground mode and a background mode, the method comprising:
playing back audio via one or more speakers while operating in the background mode, wherein the first playback device is configured to duck frequencies of the audio corresponding to human voice when operating in the background mode;
detecting occurrence of a first trigger condition corresponding to the foreground mode;
based on detecting the occurrence of the first trigger condition corresponding to the foreground mode, switching the first playback device from operating in the background mode to operating in the foreground mode; and
playing back the audio via one or more speakers while operating in the foreground mode, wherein the first playback device is configured to forego ducking when operating in the background mode.

20. A tangible, non-transitory computer-readable medium including instructions that are executable by at least one processor of a first playback device in a media playback system to:
play back audio via one or more speakers while operating in a background mode, wherein the first playback device is configured to duck frequencies of the audio corresponding to human voice when operating in the background mode, wherein the first playback device is operable in a plurality of noncontemporary modes comprising a foreground mode and the background mode;
detect occurrence of a first trigger condition corresponding to the foreground mode;
based on detecting the occurrence of the first trigger condition corresponding to the foreground mode, switch the first playback device from operating in the background mode to operating in the foreground mode; and
play back the audio via one or more speakers while operating in the foreground mode, wherein the first playback device is configured to forego ducking when operating in the background mode.
